(19) United States
(12) Patent Application Publication
(10) Pub. No.: US 2026/0324232 A1
(43) Pub. Date: Oct. 15, 2026

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Changchang LIU, Beijing (CN); Zhenglong YAN, Beijing (CN); Ling SHI, Beijing (CN)

(21) Appl. No.: 18/856,891

(22) PCT Filed: Dec. 20, 2023
(86) PCT No.: PCT/CN2023/140335

§ 371 Date: Oct. 15, 2024

(51) Int. Cl. H10K 59/131; H10K 59/12; H10K 59/121; H10K 59/126; H10K 59/80

(52) U.S. Cl. CPC H10K 59/1315; H10K 59/1201; H10K 59/1213; H10K 59/126; H10K 59/80515

(57) ABSTRACT

A display substrate and a manufacturing method therefor, and a display apparatus. A display substrate includes a drive circuit layer and a light emitting structure layer disposed on a base substrate. The drive circuit layer includes a plurality of circuit units, a circuit unit includes at least a pixel drive circuit. The light emitting structure layer includes a plurality of light emitting units, a light emitting unit includes at least an anode, the anode includes an anode main body portion and an anode connection portion, one end of the anode connection portion is connected with the anode main body portion, the other end is connected to the pixel drive circuit. At least one circuit unit further includes a shield electrode, an orthographic projection of the shield electrode is at least partially overlapped with an orthographic projection of a second anode centerline of at least one anode, on the base substrate.

### CROSS-REFERENCE TO RELATED APPLICATION

The present application is a U.S. National Phase Entry of International Application No. PCT/CN2023/140335 having an international filing date of Dec. 20, 2023, the entire content of which is hereby incorporated by reference.

### TECHNICAL FIELD

The present disclosure relates to, but is not limited to, the field of display technologies, and particularly to a display substrate and a manufacturing method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In one aspect, the present disclosure provides a drive circuit layer arranged on a base substrate and a light emitting structure layer arranged on a side of the drive circuit layer away from the base substrate. The drive circuit layer includes a plurality of circuit units, at least one circuit unit includes at least a pixel drive circuit and a first power supply line, the first power supply line is configured to provide a first power supply signal to the pixel drive circuit. The light emitting structure layer includes a plurality of light emitting units, at least one light emitting unit includes at least an anode, the anode includes an anode main body portion and an anode connection portion, one end of the anode connection portion is connected with the anode main body portion, and another end of the anode connection portion is connected with the pixel drive circuit. The at least one circuit unit further includes a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.

In another aspect, the present disclosure also provides a display apparatus, including the display substrate described above.

In another aspect, the present disclosure further provides a preparation method for a display substrate, including:
forming a drive circuit layer on a base substrate, herein the drive circuit layer includes a plurality of circuit units, at least one circuit unit includes at least a pixel drive circuit and a first power supply line, the first power supply line is configured to provide a first power supply signal to the pixel drive circuit; the at least one circuit unit further includes a shield electrode, wherein the shield electrode is connected with the first power supply line; and
forming a light emitting structure layer on the drive circuit layer, wherein the light emitting structure layer includes a plurality of light emitting units, at least one light emitting unit includes at least an anode, the anode includes an anode main body portion and an anode connection portion, one end of the anode connection portion is connected with the anode main body portion, and another end of the anode connection portion is connected with the pixel drive circuit; the at least one circuit unit further includes a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, but do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a driving timing diagram of a pixel drive circuit shown in FIG. 4.

FIG. 6 is a schematic diagram of a planar structure of a display substrate according to an exemplary embodiment of the present disclosure.

FIG. 7 is a schematic diagram of a planar structure of another display substrate according to an exemplary embodiment of the present disclosure.

FIG. 8 is a schematic diagram after a pattern of a first semiconductor layer is formed according to an embodiment of the present disclosure.

FIGS. 9A and 9B are schematic diagrams obtained after a pattern of a first conductive layer is formed according to an embodiment of the present disclosure.

FIGS. 10A and 10B are schematic diagrams after a pattern of a second conductive layer is formed according to an embodiment of the present disclosure.

FIGS. 11A and 11B are schematic diagrams after a pattern of a second semiconductor layer is formed according to an embodiment of the present disclosure.

FIGS. 12A and 12B are schematic diagrams after a pattern of a third conductive layer is formed according to an embodiment of the present disclosure.

FIG. 13 is a schematic diagram after a pattern of a sixth insulation layer is formed according to an embodiment of the present disclosure.

FIGS. 14A and 14B are schematic diagrams after a pattern of a fourth conductive layer is formed according to an embodiment of the present disclosure.

FIGS. 14C and 14D are schematic diagrams of initial signal lines in a mesh structure in FIG. 14A.

FIG. 15 is a schematic diagram after a pattern of a first planarization layer is formed according to an embodiment of the present disclosure.

FIGS. 16A and 16B are schematic diagrams after a pattern of a fifth conductive layer is formed in accordance with an embodiment of the present disclosure.

FIG. 17 is a schematic diagram after a pattern of a second planarization layer is formed according to an embodiment of the present disclosure.

FIGS. 18A and 18B are schematic diagrams after a pattern of a sixth conductive layer is formed in accordance with an embodiment of the present disclosure.

FIG. 19 is a schematic diagram after a pattern of a third planarization layer is formed according to an embodiment of the present disclosure.

FIGS. 20A and 20B are schematic diagrams after a pattern of an anode conductive layer is formed according to an embodiment of the present disclosure.

Reference sings are descrived as follows.

| | | |
|---|---|---|
| 11-First active layer; | 12-Second active layer; | 13-Third active layer; |
| 14-Fourth active layer; | 15-Fifth active layer; | 16-Sixth active layer; |
| 17-Seventh active layer; | 18- Eighth active layer; | 21-First scan signal line; |
| 22-Second scan signal line | 23-Third scan signal line; | 24-Fourth scan signal line; |
| 25-Light emitting control line; | 31-First shielding line; | 32-Second shielding line; |
| 33-First initial connection electrode; | 41-First initial signal line; | 42-Second initial signal line; |
| 43-Third initial signal line; | 44-First initial connection | 45-Second initial connection |
| | line; | line; |
| 46-Third initial connection | 51-First connection electrode; | 52-Second connection |
| line; | | electrode; |
| 53-Third connection | 54-Fourth connection electrode; | 55-Fifth connection electrode; |
| electrode; | | |
| 56-Second initial connection | 61-Eleventh connection | 62-Twelfth connection |
| electrode; | electrode | electrode; |
| 63-Thirteenth connection | 71-First power supply line; | 72-Data connection line; |
| electrode | | |
| 73-Anode connection | 74-Shield electrode; | 81-First electrode plate; |
| electrode; | | |
| 82-Second electrode plate; | 83-Opening; | 84-First electrode plate |
| | | connection line; |
| 85-Second electrode plate | 90-Anode; | 101-Base substrate; |
| connection line; | | |
| 102-Drive circuit layer; | 103-Light emitting structure | 104-Encapsulation structure |
| | layer; | layer. |

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 800 and below 100°, and thus may include a state in which the angle is above 850 and below 95°.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc. In the present disclosure, “about” refers to that a boundary is not defined so strictly and numerical values within a range of process and measurement errors are allowed.

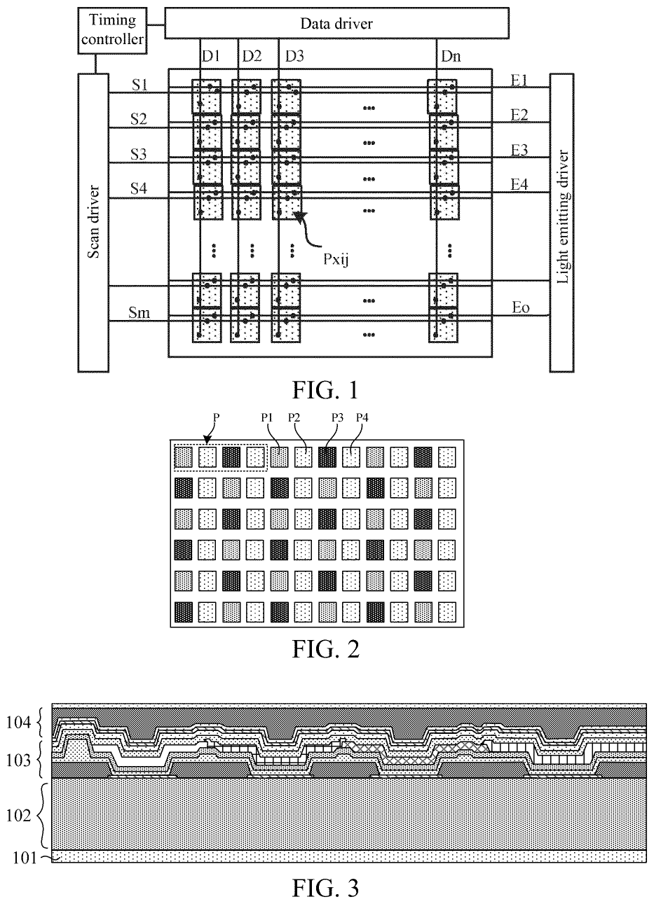

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn by using the grayscale value and the control signal that are received from the timing controller. For example, the data driver may sample the gray scale value by using the clock signal and apply a data voltage corresponding to the gray scale value to the data signal lines D1 to Dn by taking a pixel row as a unit, where n may be a natural number. The scan driver may generate a scan signal to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, where m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, where o may be a natural number. In an exemplary implementation, the pixel array may be disposed on the display substrate.

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light of a corresponding brightness in response to the current output by the pixel drive circuit of the sub-pixel where the light emitting device is located.

In an exemplary implementation, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary implementation, a sub-pixel may be in a shape of a rectangle, a rhombus, a pentagon, or a hexagon. Four sub-pixels may be arranged in a manner to stand side by side horizontally, in a manner to stand side by side vertically, or in a square-shaped arrangement, etc., which is not limited here in the present disclosure.

In some possible embodiments, the pixel unit may include three sub-pixels, the first sub-pixel P1 may be a red sub-pixel (R) that emits red light, the second sub-pixel P2 may be a green sub-pixel (G) that emits green light, and the third sub-pixel P3 may be a blue sub-pixel (B) that emits blue light, and the three sub-pixels may be arranged horizontally, vertically, or in a shape of Chinese character “ [symbol] ”, which is not limited herein.

FIG. 3 is a schematic diagram of a sectional structure of a display substrate, illustrating a structure of four sub-pixels in a display region. As shown in FIG. 3, on a plane perpendicular to the display substrate, the display substrate may include a drive circuit layer 102 disposed on a base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible substrate, or may be a rigid substrate. The drive circuit layer 102 may include a plurality of circuit units, each of which may at least include a pixel drive circuit composed of a plurality of transistors and a storage capacitor. The light emitting structure layer 103 may include multiple light emitting units, each light emitting unit may include a light emitting device, and the light emitting device may at least include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary implementation of the present disclosure provides a display substrate. In an exemplary embodiment, the display substrate includes a drive circuit layer arranged on a base substrate and a light emitting structure layer arranged on a side of the drive circuit layer away from the base substrate. Herein the drive circuit layer includes a plurality of circuit units, at least one circuit unit includes at least a pixel drive circuit and a first power supply line, the first power supply line is configured to provide a first power supply signal to the pixel drive circuit. The light emitting structure layer includes a plurality of light emitting units, at least one light emitting unit includes at least an anode, the anode includes an anode main body portion and an anode connection portion, one end of the anode connection portion is connected with the anode main body portion, and the other end of the anode connection portion is connected with the pixel drive circuit. The at least one circuit unit further includes a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.

In an exemplary embodiment, the pixel drive circuit includes at least a second transistor as a compensation transistor and a third transistor as a drive transistor, a gate electrode of the second transistor is connected with a first scan signal line, a first electrode of the second transistor is connected with a second electrode of the third transistor through a second node electrode, and a second electrode of the second transistor is connected with a gate electrode of the third transistor through a first node electrode. An orthographic projection of the anode connection portion on the base substrate is not overlapped with an orthographic projection of the second node electrode on the base substrate.

In an exemplary embodiment, an orthographic projection of the first power supply line on the base substrate is not overlapped with an orthographic projection of the second node electrode on the base substrate.

In an exemplary embodiment, the shield electrode is arranged between second node electrodes of two circuit units adjacent in the first direction.

In an exemplary embodiment, an orthographic projection of the shield electrode on the base substrate is not overlapped with an orthographic projection of the second node electrode on the base substrate.

In an exemplary implementations, an orthographic projection of the first node electrode on the base substrate is at least partially overlapped with an orthographic projection of the first scan signal line on the base substrate.

In an exemplary embodiment, the at least one circuit unit further includes a first initial signal line extending along the first direction and a first initial connection line extending along the second direction, herein the first initial signal line is configured to provide a first initial signal to the pixel drive circuit, and the first initial connection line is connected with the first initial signal line, thus forming a mesh communication structure transmitting the first initial signal, and/or, the at least one circuit unit further includes a second initial signal line extending along the first direction and a second initial connection line extending along the second direction, herein the second initial signal line is configured to provide a second initial signal to the pixel drive circuit, and the second initial connection line is connected with the second initial signal line, thus forming a mesh communication structure transmitting the second initial signal, and/or, the at least one circuit unit further includes a third initial signal line extending along the first direction and a third initial connection line extending along the second direction, herein the third initial signal line is configured to provide a third initial signal to the pixel drive circuit, and the third initial connection line is connected with the third initial signal line, thus forming a mesh communication structure transmitting the third initial signal.

In an exemplary embodiment, at least one of the first initial connection line, the second initial connection line, and the third initial connection line includes a first initial connection electrode and a second initial connection electrode connected with each other. In a direction perpendicular to the base substrate, the drive circuit layer includes a plurality of conductive layers, the first initial connection electrode and the second initial connection electrode are arranged in different conductive layers.

A display substrate according to an exemplary embodiment of the present disclosure is illustrated below by some examples.

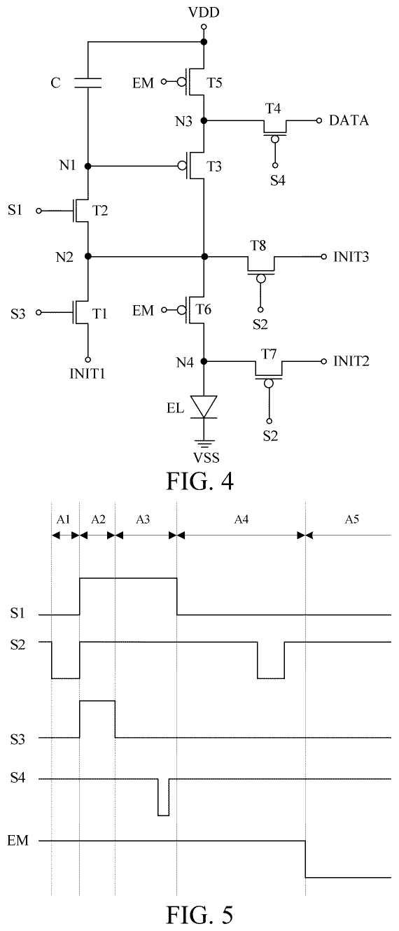

FIG. 4 is a schematic diagram of an equivalent circuit of a pixel drive circuit according to an exemplary embodiment of the present disclosure. As shown in FIG. 4, the pixel drive circuit may include eight transistors (a first transistor T1 to an eighth transistor T8) and one storage capacitor C, and the pixel drive circuit is connected to 10 signal lines (a first scan signal line S1, a second scan signal line S2, a third scan signal line S3, a fourth scan signal line S4, a light emitting signal line EM, a first initial signal line INIT1, a second initial signal line INIT2, a third initial signal line INIT3, a data signal line DATA and a first power supply line VDD), respectively.

In an exemplary implementation, the pixel drive circuit may include a first node N1, a second node N2, a third node N3, and a fourth node N4. The first node N1 is respectively connected to a second electrode of the second transistor T2, a gate electrode of the third transistor T3 and a first end of the storage capacitor C. The second node N2 is respectively connected to a second electrode of the first transistor T1, a first electrode of the second transistor T2, a second electrode of the third transistor T3, a first electrode of the sixth transistor T6 and a second electrode of the eighth transistor T8. The third node N3 is respectively connected to a first electrode of the third transistor T3, a second electrode of the fourth transistor T4 and a second electrode of the fifth transistor T5. The fourth node N4 is respectively connected to a second electrode of the sixth transistor T6 and a second electrode of the seventh transistor T7.

In an exemplary embodiment, the first end of the storage capacitor C is connected with the first node N1, and a second end of the storage capacitor C is connected with the first power supply line VDD.

In an exemplary embodiment, the first transistor T1 may be referred to as a first initialization transistor, a gate electrode of the first transistor T1 is connected to the third scan signal line S3, a first electrode of the first transistor T1 is connected to the first initial signal line INIT1, and a second electrode of the first transistor T1 is connected to the third node N2.

In an exemplary implementation, the second transistor T2 may be referred to as a compensation transistor, a gate electrode of the second transistor T2 is connected with the first scan signal line S1, the first electrode of the second transistor T2 is connected with the first node N2, and the second electrode of the second transistor T2 is connected with the first node N1.

In an exemplary embodiment, the third transistor T3 may be referred to as a drive transistor, the gate electrode of the third transistor T3 is connected to the first node N1, the first electrode of the third transistor T3 is connected to the third node N3, and the second electrode of the third transistor T3 is connected to the second node N2.

In an exemplary implementation, the fourth transistor T4 may be referred to as a data write transistor, a gate electrode of the fourth transistor T4 is connected with the fourth scan signal line S4, a first electrode of the fourth transistor T4 is connected with the data signal line DATA, and the second electrode of the fourth transistor T4 is connected with the third node N3.

In an exemplary embodiment, the fifth transistor T5 may be referred to as a first light emitting control transistor, a gate electrode of the fifth transistor T5 is connected to the light emitting signal line EM, a first electrode of the fifth transistor T5 is connected to the first power supply line VDD, and the second electrode of the fifth transistor T5 is connected to the third node N3.

In an exemplary embodiment, the sixth transistor T6 may be referred to as a second light emitting control transistor, a gate electrode of the sixth transistor T6 is connected to the light emitting signal line EM, the first electrode of the sixth transistor T6 is connected to the second node N2, and the second electrode of the sixth transistor T6 is connected to the fourth node N4.

In an exemplary embodiment, the seventh transistor T7 may referred to as a second initialization transistor, a gate electrode of the seventh transistor T7 is connected to the second scan signal line S2, a first electrode of the seventh transistor T7 is connected to the second initial signal line INIT2, and the second electrode of the seventh transistor T7 is connected to the fourth node N4.

In an exemplary embodiment, the eighth transistor T8 may be referred to as a third initialization transistor, a gate electrode of the eighth transistor T8 is connected to the second scan signal line S2, a first electrode of the eighth transistor T8 is connected to the first initial signal line INIT3, and the second electrode of the eighth transistor T8 is connected to the second node N2.

In an exemplary embodiment, a first electrode of a light emitting device EL is connected to the fourth node N4, and a second electrode of the light emitting device EL is connected to a second power supply line VSS. The light emitting device EL may be an OLED including a first electrode (anode), an organic light emitting layer, and a second electrode (cathode) which are stacked, or may be a QLED including a first electrode, a quantum dot light emitting layer, and a second electrode which are stacked.

In an exemplary implementation, a signal of the first power supply line VDD is a high-level signal continuously provided, and a signal of the second power supply line VSS is a low-level signal continuously provided.

In some possible exemplary implementations, the first to eighth transistors T1 to T8 in the pixel drive circuit may be P-type transistors or may be N-type transistors. In some other possible exemplary implementations, the first to eighth transistors T1 to T8 in the pixel drive circuit may include P-type transistors and N-type transistors.

In an exemplary implementation, the first transistor T1 to the eighth transistor T8 in pixel drive circuit may be low temperature polysilicon transistors, or may be oxide transistors, or may be a low temperature polysilicon transistor(s) and an oxide transistor(s). An active layer of a low temperature poly silicon transistor is made of Low Temperature Poly silicon (LTPS for short), and an active layer of an oxide transistor is made of an oxide semiconductor (Oxide). The low temperature polysilicon transistor has advantages such as a high migration rate and fast charging, and the oxide transistor has advantages such as a low drain current. The low temperature polysilicon transistor and the oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

As shown in FIG. 4, in the present exemplary embodiment, the first transistor T1 and the second transistor T2 in the pixel drive circuit may employ an oxide transistor(s) (N-type transistor(s)), and the third transistor T3 to the eighth transistor T8 may employ a low temperature poly-silicon transistor(s) (P-type transistor(s)).

FIG. 5 is a driving timing diagram of a pixel drive circuit shown in FIG. 4. As shown in FIG. 5, in an exemplary embodiment, the working process of the pixel drive circuit may include the first stage to the fifth stage.

A first stage A1 may be referred to as a reset stage for the second node N2 and the fourth node N4. The signals of the first scan signal line S1, the second scan signal line S2, and the third scan signal line S3 are low-level signals, and the signals of the fourth scan signal line S4 and the light emitting signal line EM are high-level signals, so that the seventh transistor T7 and the eighth transistor T8 are turned on and the other switch transistors are turned off.

The seventh transistor T7 is turned on so that a signal of the second initial signal line INIT2 is supplied to the fourth node N4, the first electrode of the light emitting device EL is initialized (reset), and the original charge in the first electrode of the light emitting device EL is cleared, so that the potential of the fourth node N4 is Vinit2. The eighth transistor T8 is turned on so that a signal of the third initial signal line INIT3 is supplied to the second node N2, and the second node N2 is initialized (reset) so that the potential of the second node N2 is Vinit3.

A second stage A2 may be referred to as a reset stage for the first node N1 and the second transistor T2. The signals of the first scan signal line S1, the second scan signal line S2, the third scan signal line S3, the fourth scan signal line S4, and the light emitting signal line EM are high-level signals, so that the first transistor T1 and the second transistor T2 are turned on, and the other switch transistors are turned off.

The first transistor T1 and the second transistor T2 are turned on so that the signal of the first initial signal line INIT1 is supplied to the first node N1 and the second node N2, respectively, and the first node N1 and the second node N2 are initialized (reset), and the original charge in the first node N1 is cleared, so that the potentials of the first node N1 and the second node N2 are Vinit1.

A third stage A3 may be referred to as the data write stage. The signal of the third scan signal line S3 is a low-level signal, the signal of the fourth scan signal line S4 is a low-level signal for a short period of time, and the signals of the first scan signal line S1, the second scan signal line S2, and the light emitting signal line EM are high-level signals, so that the second transistor T2 and the fourth transistor T4 are turned on and the other switch transistors are turned off.

The second transistor T2 is turned on so that the first node N1 and the second node N2 are turned on. Since the third transistor T3 is turned on constantly at this stage, the fourth transistor T4 is turned on so that the data signal output from the DATA signal line DATA is supplied to the first node N1 through the third node N3, the turned on third transistor T3, the second node N2, and the turned on second transistor T2, and a difference between the data voltage output from the data signal line DATA and a threshold voltage of the third transistor T3 is charged to the storage capacitor C. The voltage of the first node N1 is Vd−|Vth|, Vd is the data voltage output from the data signal line DATA, and Vth is the threshold voltage of the third transistor T3.

A fourth stage A4 may be referred to as a reset stage for the second node N2, the third node N3, and the fourth node N4.

The signals of the first scan signal line S1 and the third scan signal line S3 are low-level signals, the signal of the second scan signal line S2 is a low-level signal for a short period of time, and the signals of the fourth scan signal line S4 and the light emitting signal line EM are high-level signals, so that the second transistor T7 and the eighth transistor T8 are turned on and the other switch transistors are turned off.

The seventh transistor T7 is turned on so that the signal of the second initial signal line INIT2 is provided to the fourth node N4, since the third transistor T3 is turned on constantly, the eighth transistor T8 is turned on so that the signal of the third initial signal line INIT3 is provided to the second node N2 and the third node N3, to reset the second node N2, the third node N3 and the fourth node N4 respectively, potentials of the second node N2 and the third node N3 are Vinit3 and the potential of the fourth node N4 is Vinit2. In this stage, the second node N2, the third node N3 and the fourth node N4 are reset, which can eliminate and improve hysteresis bias caused by a difference in gray scales between adjacent pixels, reduce the hysteresis bias, and also periodically reset the OLED anode to improve the low-frequency flickering.

A fifth stage A5 may be referred to as a light emitting stage. The signals of the first scan signal line S1, the third scan signal line S3, and the light emitting signal line EM are low-level signals, and the signals of the second scan signal line S2 and the fourth scan signal line S4 are high-level signals, so that the fifth transistor T5 and the sixth transistor T6 are turned on and the other switch transistors are turned off.

The fifth transistor T5 and the sixth transistor T6 are turned on, so that the power supply voltage output from the first power supply line VDD is supplied as the drive voltage to the first electrode of the light emitting device EL through the turned-on fifth transistor T5, the third node N3, the turned-on third transistor T3, the second node N2, and the turned-on sixth transistor T6, to drive the light emitting device EL to emit light.

In the light emitting stage, the driving current of the third transistor T3 of each pixel drive circuit is not affected by the threshold voltage of the third transistor T3, thereby eliminating the influence of the threshold voltage of the third transistor T3 on the driving current, ensuring that the display brightness of the display product is uniform, and improving the display effect of the entire display product.

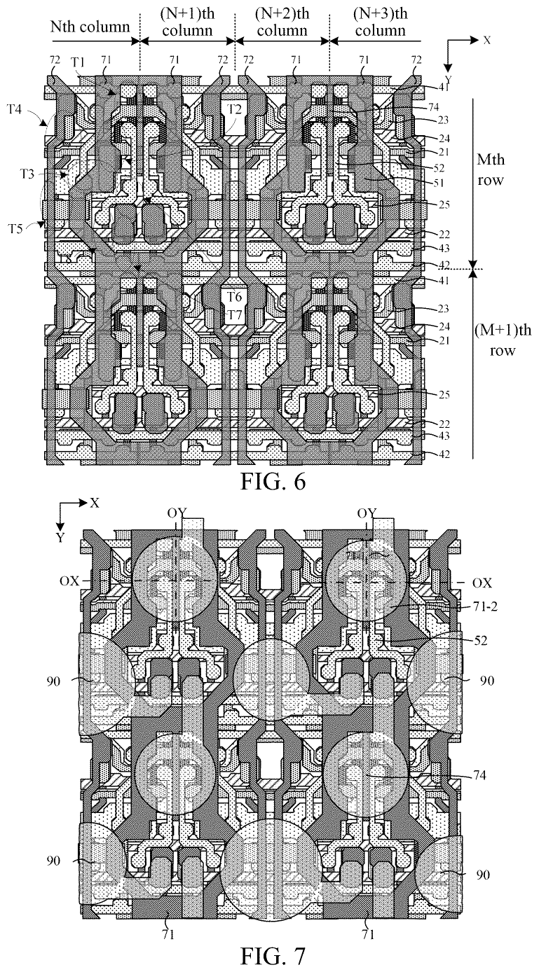

FIG. 6 is a schematic diagram of a planar structure of a display substrate according to an exemplary embodiment of the present disclosure, illustrating planar structures of a plurality of circuit units (2 unit rows and 4 unit columns). In an exemplary embodiment, on a direction perpendicular to the display substrate, the display substrate according to an exemplary embodiment of the present disclosure may include a drive circuit layer disposed on the base substrate and a light emitting structure layer disposed on a side of the drive circuit layer away from the base substrate. On a plane parallel to the display substrate, the drive circuit layer may include a plurality of circuit units, at least one circuit unit may include a pixel drive circuit configured to output a corresponding current to the connected light emitting device. The light emitting structure layer may include a plurality of light emitting units, at least one of the light emitting units may include a light emitting device connected to a pixel drive circuit of the corresponding circuit unit. The light emitting device is configured to emit light of a corresponding brightness in response to a current output by the pixel drive circuit connected to the light emitting device.

In an exemplary embodiment, the circuit units mentioned in the present disclosure are regions divided according to pixel drive circuits. The light emitting units mentioned in the present disclosure are regions divided according to light emitting devices. In an exemplary implementation, a position of an orthographic projection of a light emitting unit on the base substrate may correspond to a position of an orthographic projection of a circuit unit on the base substrate, or a position of an orthographic projection of a light emitting unit on the base substrate may not correspond to a position of an orthographic projection of a circuit unit on the base substrate.

In an exemplary implementation, the plurality of circuit units may form a plurality of unit rows and a plurality of unit columns, the plurality of circuit units in each unit row are sequentially arranged along the first direction X, and the plurality of unit rows are sequentially arranged along a second direction Y, constituting a circuit unit array arranged in an array, and the first direction X intersects with the second direction Y.

As shown in FIG. 6, the at least one circuit unit may include a pixel drive circuit, and a first scan signal line 21, a second scan signal line 22, a third scan signal line 23, a fourth scan signal line 24, a light emitting signal line 25, a first initial signal line 41, a second initial signal line 42, a third initial signal line 43, a first power supply line 71, and a data signal line 72 connected to the pixel drive circuit. In an exemplary embodiment, the first scan signal line 21, the second scan signal line 22, the third scan signal line 23, the fourth scan signal line 24, the light emitting signal line 25, the first initial signal line 41, the second initial signal line 42, and the third initial signal line 43 may be in a shape of a straight line or a bending line in which a main portion extends in the first direction X, and the first power supply line 71 and the data signal line 72 may be in a shape of a straight line or a bending line in which a main portion extends in the second direction Y. In an exemplary embodiment, the first scan signal line 21, the second scan signal line 22, the third scan signal line 23, and the fourth scan signal line 24 are configured to provide a scan signal to the pixel drive circuit, the light emitting signal line 25 is configured to provide a light emitting control signal to the pixel drive circuit, the first initial signal line 41, the second initial signal line 42, and the third initial signal line 43 are configured to provide an initial signal to the pixel drive circuit, the first power supply line 71 is configured to provide a first power supply signal to the pixel drive circuit, and the data signal line 72 is configured to provide a data signal to the pixel drive circuit.

In the present disclosure, “A extends along a B direction” refers to that A may include a main portion and a secondary portion connected with the main portion, herein the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”.

In an exemplary implementation, the pixel drive circuit in at least one circuit unit may include a storage capacitor and a plurality of transistors, the storage capacitor may include a first electrode plate and a second electrode plate which are stacked, the plurality of transistors may include a first transistor T1 as a first initialization transistor, a second transistor T2 as a compensation transistor, a third transistor T3 as a drive transistor, a fourth transistor T4 as a data write transistor, a fifth transistor T5 as a first light emitting control transistor, a sixth transistor T6 as a second light emitting control transistor, a seventh transistor T7 as a second initialization transistor, and an eighth transistor T8 as a third initialization transistor. The first transistor T1 and the second transistor T2 are oxide transistors, and the third transistor T3 to the eighth transistor T8 are low temperature poly-silicon transistors.

In an exemplary implementation, a gate electrode of the first transistor T1 is connected to the third scan signal line 23, a first electrode of the first transistor T1 is connected to the first initial signal line 41, and a second electrode of the first transistor T1 is connected to a first electrode of the second transistor T2. A gate electrode of the second transistor T2 is connected to the first scan signal line 21, the first electrode of the second transistor T2 is connected to a second electrode of the third transistor T3 through a second connection electrode 52 which is used as a second node electrode, and a second electrode of the second transistor T2 is connected to a gate electrode (first electrode plate) of the third transistor T3 through a first connection electrode 51 which is used as a first node electrode. A gate electrode of the fourth transistor T4 is connected to the fourth scan signal line 24, a first electrode of the fourth transistor T4 is connected to the data signal line 72, and a second electrode of the fourth transistor T4 is connected to the first electrode of the third transistor T3. A gate electrode of the fifth transistor T5 is connected with the light emitting signal line 25, a first electrode of the fifth transistor T5 is connected with the first power supply line 71, and a second electrode of the fifth transistor T5 is connected with the first electrode of the third transistor T3. The gate electrode of the sixth transistor T6 is connected to the light emitting signal line 25, the first electrode of the sixth transistor T6 is connected to the second electrode of the third transistor T3, and the second electrode of the sixth transistor T6 is connected to the second electrode of the seventh transistor T7. A gate electrode of the seventh transistor T7 is connected with a second scan signal line 22, and a first electrode of the seventh transistor T7 is connected with a second initial signal line 42. The gate electrode of the eighth transistor T8 is connected to the second scan signal line 22, the first electrode of the eighth transistor T8 is connected to the third initial signal line 43, and the second electrode of the eighth transistor T8 is connected to the second electrode of the third transistor T3 through the second connection electrode 52.

In an exemplary implementation, a part of the first power supply lines 71 of two circuit units adjacent in the first direction X may be an integrated structure connected to each other.

In an exemplary implementation, an orthographic projection of the first power supply line 71 on the base substrate is at least partially overlapped with an orthographic projection of the first connection electrode 51 on the base substrate.

In an exemplary implementation, the orthographic projection of the first power supply line 71 on the base substrate is at least partially overlapped with the orthographic projection of the active layer of the second transistor T2 on the base substrate.

In an exemplary implementation, the orthographic projection of the first connection electrode 51 on the base substrate is at least partially overlapped with the orthographic projection of the first scan signal line 21 on the base substrate.

In an exemplary implementation, the orthographic projection of the first power supply line 71 on the base substrate is not overlapped with the orthographic projection of the second connection electrode 52 on the base substrate.

In an exemplary implementation, the at least one circuit unit further includes a shield electrode 74 connected to the first power supply line 71 and disposed between the second connection electrodes 52 of two circuit units adjacent in the first direction X.

In an exemplary implementation, an orthographic projection of the shield electrode 74 on the base substrate is not overlapped with the orthographic projection of the second connection electrode 52 on the base substrate.

In an exemplary implementation, the orthographic projection of the second connection electrode 52 on the base substrate is not overlapped with the orthographic projection of the fourth scan signal line 24 on the base substrate.

FIG. 7 is a schematic diagram of a planar structure of another display substrate according to an exemplary embodiment of the present disclosure, illustrating a planar structure of anodes in a plurality of light emitting units. In an exemplary implementation, the light emitting structure layer may include a plurality of light emitting units, at least one light emitting unit may include a light emitting device, and at least one light emitting device may include an anode 90 connected to a pixel drive circuit of a corresponding circuit unit.

As shown in FIG. 7, at least one anode 90 may include an anode main body portion and an anode connection portion, the shape of the anode main body portion may be circular or oval, the shape of the anode connection portion may be strip, one end of the anode connection portion is directly connected to the anode main body portion, and the other end of the anode connection portion is connected to the pixel drive circuit through a via.

In an exemplary implementation, the anode main body portion of the at least one anode may have a first anode centerline OX and the second anode centerline OY, herein the first anode centerline OX may be a straight line that bisects the anode main body portion of the anode in the second direction Y and extends along the first direction X, and the second anode centerline OY may be a straight line that bisects the anode main body portion of the anode in the first direction X and extends along the second direction Y.

In an exemplary implementation, an orthographic projection of the at least one shield electrode 74 on the base substrate is at least partially overlapped with an orthographic projection of the second anode centerline OY of the at least one anode 90 on the base substrate.

In an exemplary implementation, the orthographic projection of the anode main body portion of the at least one anode 90 on the base substrate is at least partially overlapped with the orthographic projections of the two first power supply lines 71 in two circuit units adjacent in the first direction X on the base substrate, and the two first power supply lines 71 may be mirror-symmetrical with respect to the second anode centerline OY.

In an exemplary implementation, the orthographic projection of the anode connection portion of the at least one anode 90 on the base substrate is not overlapped with the orthographic projection of the second connection electrode 52 on the base substrate.

In an exemplary implementation, a first power supply block 71-1 and a second power supply block 71-2 may be provided on at least one first power supply line 71, the orthographic projection of the anode main body portion of the at least one anode 90 on the base substrate is at least partially overlapped with orthographic projections of the first power supply block 71-1 and the second power supply block 71-2 on the base substrate, and the first power supply block 71-1 and the second power supply block 71-2 may be mirror-symmetrical with respect to the first anode centerline OX.

In an exemplary implementation, the orthographic projection of the anode main body portion of the at least one anode 90 on the base substrate is at least partially overlapped with the orthographic projections of the two first power supply blocks 71-1 in the two circuit units adjacent in the first direction X on the base substrate, the two first power supply blocks 71-1 may be mirror-symmetrical with respect to the second anode centerline OY.

In an exemplary implementation, the orthographic projection of the anode main body portion of the at least one anode 90 on the base substrate is at least partially overlapped with the orthographic projections of the two second power supply blocks 71-2 in the two circuit units adjacent in the first direction X on the base substrate, the two second power supply blocks 71-2 may be mirror-symmetrical with respect to the second anode centerline OY.

In an exemplary implementation, the drive circuit layer may include a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, a second planarization layer, a sixth conductive layer, and a third planarization layer arranged sequentially on the base substrate. The first semiconductor layer may include at least active layers of the third transistors T3 to T8, the first conductive layer may include at least the second scan signal line 22, the fourth scan signal line 24 and a first electrode plate of storage capacitance, the second conductive layer may include at least a second electrode plate of the storage capacitance, the second semiconductor layer may include at least active layers of the first transistor T1 and the second transistor T2, the third conductive layer may include at least the first scan signal line 21, the third scan signal line 23 and a first initial connection electrode 33, the fourth conductive layer may include at least a second initial connection electrode 46, the fifth conductive layer may include a plurality of connection electrodes, the sixth conductive layer may include at least the first power supply line 71, the data signal line 72 and the shield electrode 74.

Exemplary description is made below through a preparation process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition; coating may be any one or more of spray coating, spin coating, and inkjet printing; and etching may be any one or more of dry etching and wet etching, which is not limited in present disclosure. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, taking 8 circuit units (2 unit rows, 4 unit columns) as an example, the preparation process of the display substrate may include the following operations.

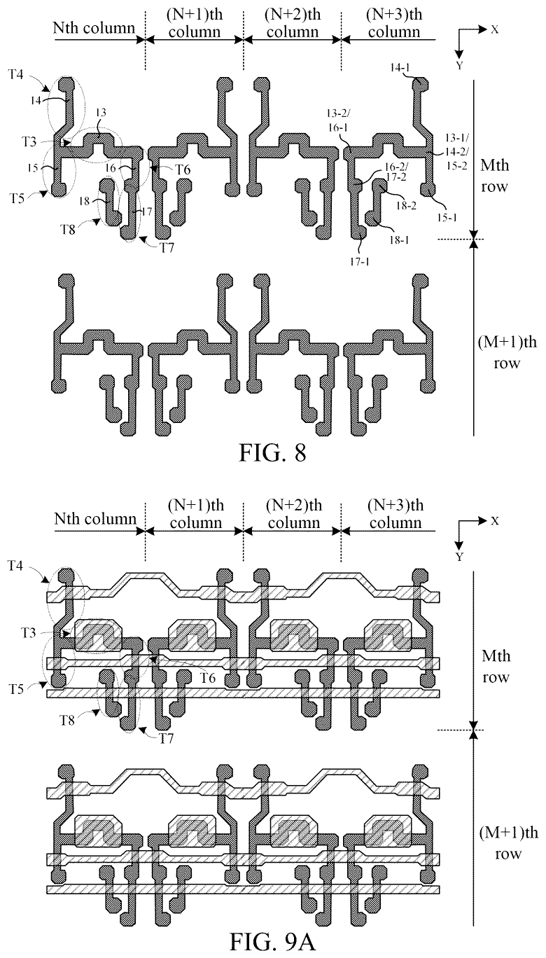

(1) A pattern of a first semiconductor layer is formed. In an exemplary implementation, forming the pattern of the first semiconductor layer may include: depositing a first insulation thin film and a first semiconductor thin film sequentially on a base substrate, and patterning the first semiconductor thin film through a patterning process to form a first insulation layer covering the base substrate and the pattern of the first semiconductor layer disposed on the first insulation layer, as shown in FIG. 8.

In an exemplary implementation, a pattern of a first semiconductor layer in each circuit unit may include a third active layer 13 of a third transistor T3 to an eighth active layer 18 of an eighth transistor T8, and the third active layer 13 to the seventh active layer 17 in the circuit unit are of an interconnected integrated structure.

In an exemplary implementation, in the first direction X, the fourth active layer 14 and the fifth active layer 15 may be located on a same side of the third active layer 13 in the present circuit unit, the sixth active layer 16 and the seventh active layer 17 may be located on a same side of the third active layer 13 in the present circuit unit, and the fifth active layer 15 and the sixth active layer 16 may be located on different sides of the third active layer 13 of the present circuit unit. In the second direction Y, the fourth active layer 14 of the circuit units in the Mth circuit row may be located on a side of the third active layer 13 away from the (M+1)th circuit row, and the fifth active layer 15, the sixth active layer 16, the seventh active layer 17, and the eighth active layer 18 of the circuit units in the Mth circuit row may be located on a side of the third active layer 13 close to circuit units of the (M+1)th unit row.

In an exemplary implementation, the third active layer 13 may have a shape of character “Ω”, and the shape of the fourth active layer 14, the fifth active layer 15, the sixth active layer 16, the seventh active layer 17 and the eighth active layer 18 may have a shape of character “I”.

In an exemplary implementation, an active layer of each transistor may include a first region, a second region, and a channel region located between the first region and the second region. In an exemplary implementation, a first region 13-1 of the third active layer 13, a second region 14-2 of the fourth active layer 14 and a second region 15-2 of the fifth active layer 15 may be interconnected, the first region 13-1 of the third active layer 13 is also used as the second region 14-2 of the fourth active layer 14 and the second region 15-2 of the fifth active layer 15 simultaneously. A second region 13-2 of the third active layer 13 is connected to a first region 16-1 of the sixth active layer 16, and the second region 13-2 of the third active layer 13 may be used as the first region 16-1 of the sixth active layer 16. A second region 16-2 of the sixth active layer 16 is connected to a second region 17-2 of the seventh active layer 17, and the second region 16-2 of the sixth active layer 16 may be used as the second region 17-2 of the seventh active layer 17. A first region 14-1 of the fourth active layer 14, a first region 15-1 of the fifth active layer 15, a first region 17-1 of the seventh active layer 17, a first region 18-1 of the eighth active layer 18, and a second region 18-2 of the eighth active layer 18 may be provided separately.

In an exemplary implementation, in a unit row, first semiconductor layers in two adjacent circuit units may be arranged symmetrically with respect to a column centerline, the column centerline may be a straight line located between two adjacent circuit units in a first direction X and extending in a second direction Y. For example, first semiconductor layers (third active layer 13 to eighth active layer 18) of the Nth unit column and the (N+1)th unit column may be arranged symmetrically with respect to a column centerline. As another example, the first semiconductor layers of the (N+1)th unit column and the (N+2)th unit column may be arranged symmetrically with respect to the column centerline.

In an exemplary implementation, first semiconductor layers in adjacent unit rows may be substantially the same.

In an exemplary implementation, the first semiconductor layer may be made of poly Silicon (p-Si), that is, the third transistor to the eighth transistor are LTPS thin film transistors. In an exemplary implementation, patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a polysilicon thin film. Subsequently, the poly silicon thin film is patterned to form the pattern of the first semiconductor layer.

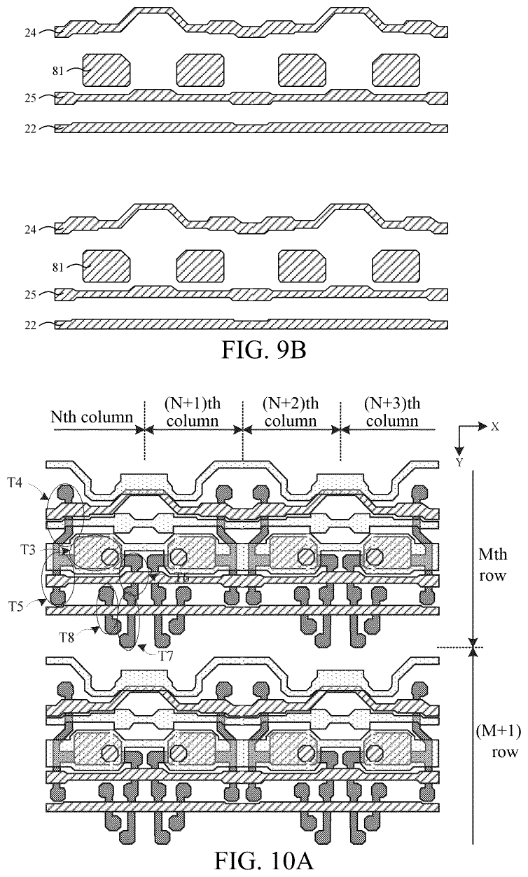

(2) A pattern of a first conductive layer is formed. In an exemplary implementation, forming the pattern of the first conductive layer may include: depositing sequentially a second insulation thin film and a first conductive thin film on the base substrate on which the aforementioned pattern is formed, and patterning the first conductive thin film through a patterning process to form a second insulation layer that covers the pattern of the first semiconductor layer and form the pattern of the first conductive layer disposed on the second insulation layer, as shown in FIG. 9A and FIG. 9B, and FIG. 9B is a schematic plan view of the first conductive layer in FIG. 9A. In an exemplary implementation, the first conductive layer may be referred to as a first gate metal (GATE1) layer.

In an exemplary implementation, the pattern of the first conductive layer in each circuit unit may at least include the second scan signal line 22, the fourth scan signal line 24, the light emitting control line 25, and the first electrode plate 81 of the storage capacitor.

In an exemplary implementation, the first electrode plate 81 may be in a shape of a rectangle, and a chamfer may be provided at a corner in a shape of a rectangle. An orthographic projection of the first electrode plate 81 on the base substrate is at least partially overlapped with an orthographic projection of the third active layer of the third transistor T3 on the base substrate. In an exemplary implementation, the first electrode plate 81 may serve as one plate of the storage capacitor and a gate electrode of the third transistor T3 simultaneously.

In an exemplary implementation, the second scan signal line 22 may be in a shape of a straight line or a bending line in which a main portion extends along the first direction X, the second scan signal line 22 in a circuit unit of the Mth unit row may be located at a side of the first electrode plate 81 of the present circuit unit close to circuit units of the (M+1)th unit row, a region where the second scan signal line 22 is overlapped with the seventh active layer in the present circuit unit serves as a gate electrode of the seventh transistor T7, and a region where the second scan signal line 22 is overlapped with the eighth active layer in the present circuit unit serves as a gate electrode of the eighth transistor T8.

In an exemplary implementation, the fourth scan signal line 24 may be in a shape of a straight line or a bending line in which a main portion extends along the first direction X, a fourth scan signal line 24 in a circuit unit of the Mth unit row may be located on a side of the first electrode plate 81 of the present circuit unit away from circuit units of the (M+1)th unit row, a region where the fourth scan signal line 24 is overlapped with a fourth active layer in the present circuit unit serves as a gate electrode of the fourth transistor T4.

In an exemplary implementation, the light emitting control line 25 may have a shape of a straight line or a bending line in which a main body portion extends along the first direction X, the light emitting control line 25 may be located between the first electrode plate 81 and the second scan signal line 22, a region where the light emitting control line 25 is overlapped with the fifth active layer of the present circuit unit serves as a gate electrode of the fifth transistor T5, and a region where the light emitting control line 25 is overlapped with the sixth active layer of the present circuit unit serves as a gate electrode of the sixth transistor T6.

In an exemplary implementation, in a unit row, first conductive layers in two adjacent circuit units may be arranged symmetrically with respect to the column centerline. For example, first conductive layers of the Nth unit column and the (N+1)th unit column may be disposed symmetrically with respect to the column centerline. As another example, the first conductive layers of the (N+1)th unit column and the (N+2)th unit column may be disposed symmetrically with respect to the column centerline.

In an exemplary implementation, first conductive layers in adjacent unit rows may be substantially the same.

In an exemplary implementation, after the pattern of the first conductive layer is formed, a conductive processing may be performed on the first semiconductor layer by using the first conductive layer as a shield, a first semiconductor layer in a region shielded by the first conductive layer forms channel regions of the third transistor T3 to the eighth transistor T8, and a first semiconductor layer in a region not shielded by the first conductive layer is made to be conductive. That is, the first regions and the second regions of the third active layer to the eighth active layer are all made to be conductive.

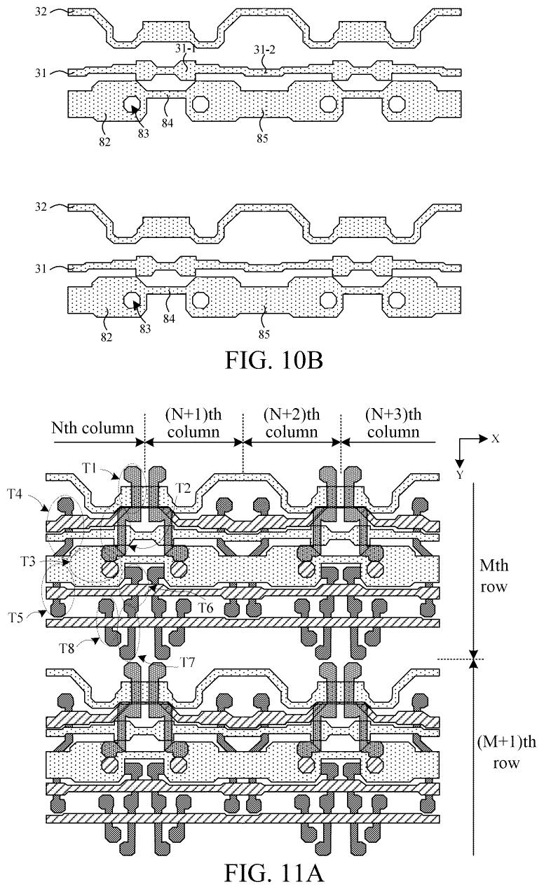

(3) A pattern of a second conductive layer is formed. In an exemplary implementation, forming a pattern of a second conductive layer may include: depositing sequentially a third insulation thin film and a second conductive thin film on the base substrate on which the aforementioned patterns are formed, and patterning the second conductive thin film through a patterning process to form a third insulation layer that covers the first conductive layer and the pattern of the second conductive layer provided on the third insulation layer, as shown in FIG. 10A and FIG. 10B. FIG. 10B is a planar schematic diagram of the second conductive layer in FIG. 10A. In an exemplary implementation, the second conductive layer may be referred to as a second gate metal (GATE2) layer.

In an exemplary implementation, the pattern of the second conductive layer in each circuit unit at least includes a first shielding line 31, a second shielding line 32 and a second electrode plate 82 of the storage capacitor.

In an exemplary implementation, a profile of second electrode plate 82 may be in a shape of a rectangle, a chamfer may be provided at a corner in a shape of a rectangle, an orthographic projection of the second electrode plate 82 on the base substrate is at least overlapped with an orthographic projection of the first electrode plate 81 on the base substrate, the second electrode plate 82 may serve as anther electrode plate of the storage capacitor, and the first electrode plate 81 and the second electrode plate 82 form the storage capacitor of the pixel drive circuit.

In an exemplary implementation, the second electrode plate 82 is provided with an opening 83. The opening 83 may have a block shape such as a rectangular and may be located in the middle of the second electrode plate 82, so that the second electrode plate 82 is formed in an annular structure. The opening 83 exposes the third insulation layer covering the first electrode plate 81, and an orthographic projection of the first electrode plate 81 on the base substrate contains an orthographic projection of the opening 83 on the base substrate. In an exemplary implementation, the opening 83 is configured to accommodate an eleventh via formed subsequently, and the eleventh via is located within the opening 83 and exposes the first electrode plate 81, so that a first connection electrode formed subsequently is connected with the first electrode plate 81.

In an exemplary implementation, a first electrode plate connection line 84 and a second electrode plate connection line 85 may be provided on the second electrode plate 82, and the first electrode plate connection line 84 and the second electrode plate connection line 85 may be provided on two sides of the second electrode plate 82 in the first direction X, respectively, and connected to the second electrode plate 82 in the adjacent circuit units in the first direction X, so that the second electrode plates 82 in the adjacent circuit units in one unit row are connected to each other. For example, the second electrode plate 82 of the Nth column and the second electrode plate 82 of the (N+1)th column may be connected to each other by the first electrode plate connection line 84. As another example, the second electrode plates 82 of the (N+1)th column and the second electrode plate 82 of the (N+2)th column are connected with each other by the second electrode plate connection line 85. Since the second electrode plate 82 in each circuit unit is connected with a first power supply line formed subsequently, by forming an integrated structure in which the second electrode plates 82 of adjacent circuit units are connected with each other, the second electrode plate 82 of the integrated structure can be multiplexed as a power supply signal line, so that a plurality of second electrode plates 82 in a unit row can be guaranteed to have a same potential, which is beneficial for improving the uniformity of the panel, avoiding poor display of the display substrate and ensuring the display effect of the display substrate.

In an exemplary implementation, the width of the first electrode plate connection line 84 and the second electrode plate connection line 85 may be different, and the width is the size in the second direction Y.

In an exemplary implementation, the first shielding line 31 may be in a shape of a straight line or a bending line in which a main portion extends in the first direction X, and the first shielding line 31 may be located between the second electrode plate 82 and the fourth scan signal line 24. In an exemplary implementation, the first shielding line 31 may be a bending line of unequal width, the width of a position where the first shielding line 31 is overlapped with a second active layer formed subsequently may be greater than the widths of other positions, and a first shielding line 31 at a wider position may serve as a shielding layer of the second transistor T2 to shield the channel area of the second transistor T2 and ensure the electrical performance of the oxide second transistor T2. In an exemplary implementation, the first shielding line 31 may serve as a bottom gate electrode of the second transistor T2 at the same time.

In an exemplary implementation, the first shielding line 31 may be in a shape of a straight line or a bending line of unequal width, and the width is the size in the second direction Y. The first shielding line 31 may include at least a first sub-shielding line segment 31-1 and a second sub-shielding line segment 31-2 connected to each other, the width of the first sub-shielding line segment 31-1 is greater than the width of the second sub-shielding line segment 31-2. In an exemplary implementation, the first sub-shielding line segment 31-1 may be provided in an area where the second active layer formed subsequently is located, an orthographic projection of the first sub-shielding line segment 31-1 on the base substrate is at least partially overlapped with an orthographic projection of the second active layer on the base substrate, and the second sub-shielding line segment 31-2 may be provided in an area outside the second active layer formed subsequently, an orthographic projection of the second sub-shielding line segment 31-2 on the base substrate is not overlapped with the orthographic projection of the second active layer on the base substrate.

In an exemplary implementation, the second shielding line 32 may be in a shape of a straight line or a bending line in which a main portion extends in the first direction X, and the second shielding line 32 may be located a side of the fourth scan signal line 24 away from the second electrode plate. In an exemplary implementation, the second bending line 32 may be a bending line of unequal width, the width of a position where the second bending line 32 is overlapped with the first active layer formed subsequently may be greater than the widths of other positions, and the second bending line 32 at a wider position may serve as a shielding layer of the first transistor T1 to shield the channel area of the first transistor T1 and ensure the electrical performance of the oxide first transistor T1. In an exemplary implementation, the second shielding line 32 may serve as the bottom gate electrode of the first transistor T1 at the same time.

In an exemplary implementation, in a unit row, second conductive layers in two adjacent circuit units may be arranged symmetrically with respect to the column centerline. For example, second conductive layers of the Nth unit column and the (N+1)th unit column may be disposed symmetrically with respect to the column centerline. As another example, the second conductive layers of the (N+1)th unit column and the (N+2)th unit column may be disposed symmetrically with respect to the column centerline.

In an exemplary implementation, second conductive layers in adjacent unit rows may be substantially the same.

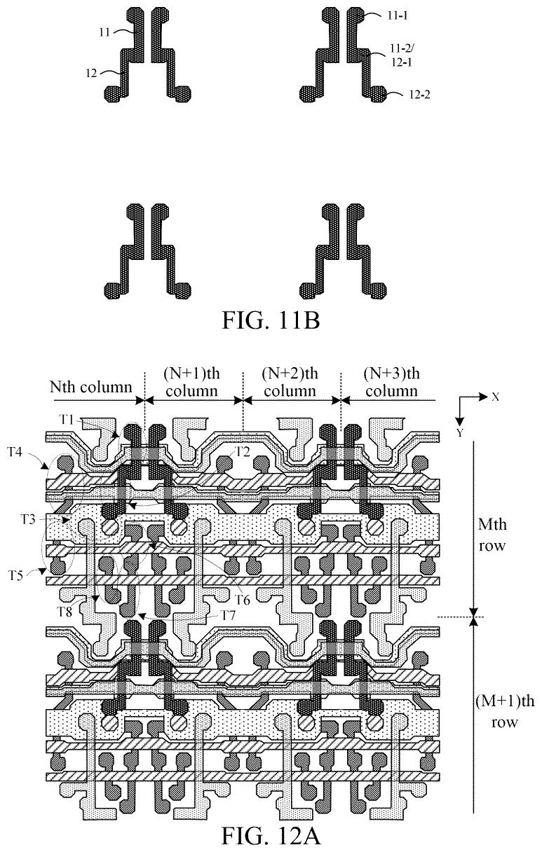

(4) A pattern of a second semiconductor layer is formed. In an exemplary implementation, forming the pattern of the second semiconductor layer may include: depositing a fourth insulation thin film and a second semiconductor thin film sequentially on the base substrate on which the aforementioned patterns are formed, patterning the second semiconductor thin film through a patterning process to form a fourth insulation layer that covers the base substrate and the pattern of the second semiconductor layer disposed on the fourth insulation layer, as shown in FIG. 11A and FIG. 11B, and FIG. 11B is a schematic plan view of the second conductive layer in FIG. 11A.

In an exemplary implementation, a pattern of a second semiconductor layer in each circuit unit at least includes a first active layer 11 of the first transistor T1 and a second active layer 12 of the second transistor T2.

In an exemplary implementation, shapes of the first active layer 11 and the second active layer 12 may be in a shape of character “I”, the orthographic projection of the first active layer 11 on the base substrate is at least partially overlapped with the orthographic projection of the second shielding line 32 on the base substrate, and the orthographic projection of the second active layer 12 on the base substrate is at least partially overlapped with the orthographic projection of the first shielding line 31 on the base substrate.

In an exemplary implementation, a first region 11-1 of the first active layer 11 may be located on the side of the second shielding line 32 away from the second electrode plate 82, a second region 12-2 of the second active layer 12 may be located on the side of the first shielding line 31 close to the second electrode plate 82, the second region 11-2 of the first active layer 11 and a first region 12-1 of the second active layer 12 may be connected to each other, and a second region 11-2 of the first active layer 11 may serve as the first region 12-1 of the second active layer 12.

In an exemplary implementation, in a unit row, second semiconductor layers in two adjacent circuit units may be arranged symmetrically with respect to the column centerline. For example, second semiconductor layers of the Nth unit column and the (N+1)th unit column may be disposed symmetrically with respect to the column centerline. As another example, the second semiconductor layer layers of the (N+1)th unit column and the (N+2)th unit column may be arranged symmetrically with respect to the column centerline.

In an exemplary implementation, second semiconductor layers in adjacent unit rows may be substantially the same.

In an exemplary implementation, the second semiconductor layer may be made of an oxide, that is, the first transistor T1 and the second transistor T2 are oxide transistors. In an exemplary implementation, the second semiconductor thin film may be made of Indium Gallium Zinc Oxide (IGZO), herein electron mobility of the Indium Gallium Zinc Oxide (IGZO) is higher than that of amorphous silicon.

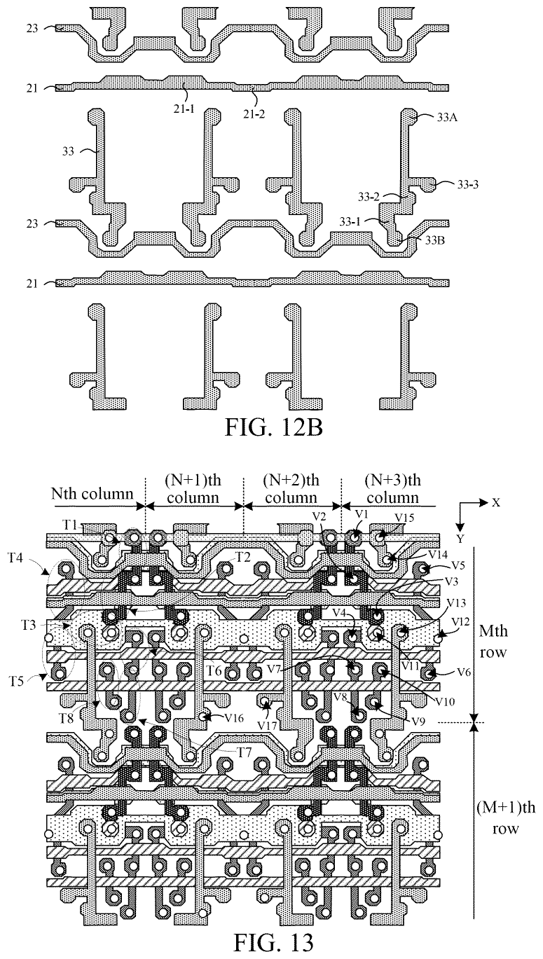

(5) A pattern of a third conductive layer is formed. In an exemplary implementation, forming the pattern of the third conductive layer may include: depositing a fifth insulation thin film and a third conductive thin film sequentially on the base substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIGS. 12A and 12B, FIG. 12B is a schematic plan view of the third conductive layer in FIG. 12A. In an exemplary implementation, the third conductive layer may be referred to as a third gate metal (GATE3) layer.

In an exemplary implementation, the third conductive layer pattern in each circuit unit includes at least a first scan signal line 21, a third scan signal line 23, and a first initial connection electrode 33.

In an exemplary implementation, the first scan signal line 21 may be in a shape of a straight line or a bending line in which a main portion extends in the first direction X, the first scan signal line 21 may be located between the second electrode plate 82 and the fourth scan signal line 24, and the region where the first scan signal line 21 is overlapped with the second active layer serves as the gate electrode of the second transistor T2.

In an exemplary implementation, an orthographic projection of the first scan signal line 21 on the base substrate is at least partially overlapped with the orthographic projection of the first shielding line 31 on the base substrate, and the first scan signal line 21 and the first shielding line 31 may be connected to the same signal source, so that the first shielding line 31 may be used as the bottom gate electrode of the second transistor T2, and the first scan signal line 21 may be used as the top gate electrode of the second transistor T2, to form the second transistor T2 of a top gate bottom gate structure.

In an exemplary implementation, the first scan signal line 21 may be a straight line or a bending line of unequal width, and the width is the size in the second direction Y. The first scan signal line 21 may include at least a first sub-scan line segment 21-1 and a second sub-scan line segment 21-2 connected to each other, the width of the first sub-scan line segment 21-1 is greater than the width of the second sub-scan line segment 21-2. In an exemplary implementation, the first sub-scan line segment 21-1 may be provided in an area where the second active layer is located, an orthographic projection of the first sub-scan line segment 21-1 on the base substrate is at least partially overlapped with an orthographic projection of the second active layer on the base substrate, and the second sub-scan line segment 21-2 may be provided in an area outside the second active layer, an orthographic projection of the second sub-scan line segment 21-2 on the base substrate is not overlapped with the orthographic projection of the second active layer on the base substrate.

In an exemplary implementation, the orthographic projection of the first sub-scan line segment 21-1 on the base substrate is at least partially overlapped with the orthographic projection of the first sub-shielding line segment 31-1 on the base substrate, and the orthographic projection of the second sub-scan line segment 21-2 on the base substrate is at least partially overlapped with the orthographic projection of the second sub-shielding line segment 31-2 on the base substrate.

In an exemplary implementation, the third scan signal line 23 may be in a shape of a straight line or a bending line in which a main portion extends along the first direction X, the third scan signal line 23 may be located at a side of the fourth scan signal line 24 away from the second electrode plate 82, and a region where the third scan signal line 23 is overlapped with the first active layer serves as the gate electrode of the first transistor T1.

In an exemplary implementation, an orthographic projection of the third scan signal line 23 on the base substrate is at least partially overlapped with the orthographic projection of the second shielding line 32 on the base substrate, and the third scan signal line 23 and the second shielding line 32 may be connected to the same signal source, so that the second shielding line 32 may be used as the bottom gate electrode of the first transistor T1, and the third scan signal line 23 may be used as the top gate electrode of the first transistor T1, to form the first transistor T1 of a top gate bottom gate structure.

In an exemplary implementation, the first initial connection electrode 33 is in a shape of a bending line in which the main portion extends in the second direction, the first initial connection electrode 33 is configured to be connected with the second initial connection electrode formed subsequently, and the first initial connection electrode and the second initial connection electrode together form an initial connection line.

In an exemplary implementation, the first initial connection electrode 33 may include a first end 33A, a second end 33B, a first connection block 33-1, a second connection block 33-2, and a third connection block 33-3. The first end 33A of the first initial connection electrode 33 is an end of the first initial connection electrode 33 close to the first scan signal line 21, and the second end 33B of the first initial connection electrode 33 is an end of the first initial connection electrode 33 close to the third scan signal line 23. The first connection block 33-1 may be provided on a side of the first end 33A close to the second end 33B, and the first connection block 33-1 is configured to be connected to the first initial signal line formed subsequently. The second connection block 33-2 may be provided on a side of the first connection block 33-1 close to the second end 33B, and the second connection block 33-2 is configured to be connected to the second initial signal line formed subsequently. The third connection block 33-3 may be provided on a side of the second connection block 33-2 close to the second end 33B, and the third connection block 33-3 is configured to be connected to the third initial signal line formed subsequently.

In an exemplary implementation, in a unit row, third conductive layers in two adjacent circuit units may be arranged symmetrically with respect to the column centerline. For example, third conductive layers of the Nth unit column and the (N+1)th unit column may be disposed symmetrically with respect to the column centerline. As another example, the third conductive layers of the (N+1)th unit column and the (N+2)th unit column may be disposed symmetrically with respect to the column centerline.

In an exemplary implementation, third conductive layers in adjacent unit rows may be substantially the same.

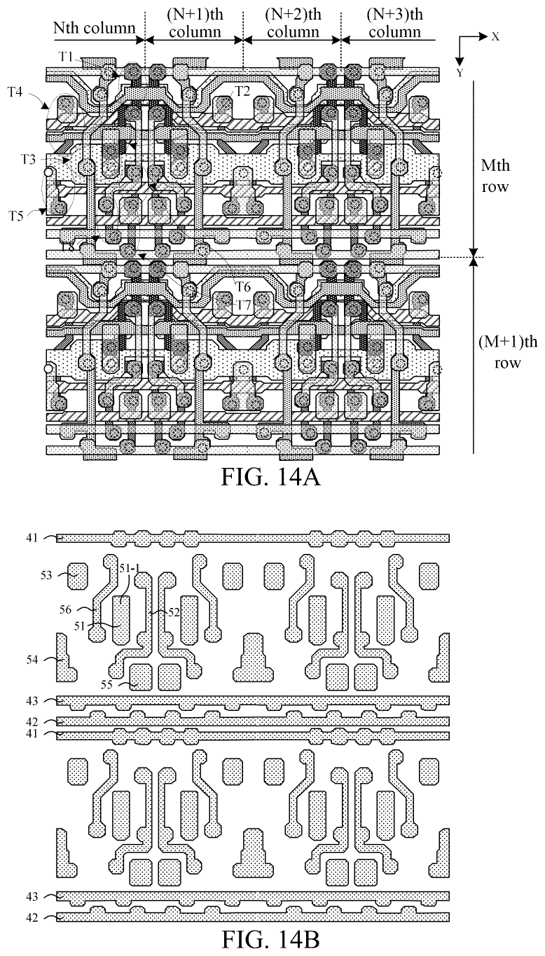

(6) A pattern of a sixth insulation layer is formed. In an exemplary implementation, forming the pattern of the sixth insulating layer may include depositing a sixth insulating thin film on the base substrate on which the aforementioned patterns are formed, patterning the sixth insulating thin film using a patterning process to form the sixth insulating layer covering the third conductive layer, and a plurality of vias are provided on the sixth insulating layer, as shown in FIG. 13.

In an exemplary implementation, the plurality of vias in each circuit unit include at least a first via V1 to a fourteenth via V14.

In an exemplary implementation, an orthographic projection of the first via V1 on the base substrate is within a range of an orthographic projection of a first region of a first active layer on the base substrate, the sixth insulation layer and the fifth insulation layer within the first via V1 are etched away to expose a surface of the first region of the first active layer, and the first via V1 is configured to enable a subsequently formed first initial signal line to be connected with the first region of the first active layer through the via V1.

In an exemplary implementation, an orthographic projection of the second via V2 on the base substrate is within a range of an orthographic projection of the second region of the first active layer (also the first region of the second active layer) on the base substrate. A sixth insulation layer and a fifth insulation layer within the second via V2 are etched away to expose a surface of the second region of the first active layer (also the first region of the second active layer), and the second via V2 is configured such that the second connection electrode formed subsequently is connected with the second region of the first active layer (also the first region of the second active layer) through this via V2.

In an exemplary implementation, in the region where the second via V2 is located, a curved portion is provided on the fourth scan signal line 24, and the curved portion protrudes in a direction away from the second electrode plate 82, so that the orthographic projection of the second via V2 on the base substrate is not overlapped with the orthographic projection of the fourth scan signal line 24 on the base substrate.

In an exemplary implementation, an orthographic projection of the third via V3 on the base substrate is within a range of an orthographic projection of a second region of a second active layer on the base substrate, the sixth insulation layer and the fifth insulation layer within the third via V3 are etched away to expose a surface of the second region of the second active layer, and the third via V3 is configured to enable a subsequently formed first connection electrode to be connected with the second region of the second active layer through the via V3.

In an exemplary implementation, an orthographic projection of the fourth via V4 on the base substrate is within an orthographic projection of the second region of the third active layer (also the first region of the sixth active layer) on the base substrate, the sixth insulating layer, the fifth insulating layer, the fourth insulating layer, the third insulating layer and the second insulating layer within the fourth via V4 are etched away to expose the surface of the second region of the third active layer (also the first region of the sixth active layer), and the fourth via V4 is configured such that a subsequently formed second connection electrode is connected to the second region of the third active layer (also the first region of the sixth active layer) through the via V4.

In an exemplary implementation, an orthographic projection of the fifth via V5 on the base substrate is within a range of an orthographic projection of the first region of the fourth active layer on the base substrate, the sixth insulation layer, the fifth insulation layer, the fourth insulation layer, the third insulation layer, and the second insulation layer within the fifth via V5 are etched away to expose a surface of the first region of the fourth active layer, and the fifth via V5 is configured such that a third connection electrode subsequently formed is connected with the first region of the fourth active layer through the via V5.

In an exemplary implementation, an orthographic projection of the sixth via V6 on the base substrate is within a range of an orthographic projection of the first region of the fifth active layer on the base substrate, the sixth insulating layer, the fifth insulating layer, the fourth insulating layer, the third insulating layer and the second insulating layer within the sixth via V6 are etched away to expose a surface of the first region of the fifth active layer, and the sixth via V6 is configured such that a subsequently formed fourth connection electrode is connected to the first region of the fifth active layer through the via V6.

In an exemplary implementation, an orthographic projection of the seventh via V7 on the base substrate is within a range of an orthographic projection of the second region of the sixth active layer (also the second region of the seventh active layer) on the base substrate. A sixth insulation layer, a fifth insulation layer, a third insulation layer and a second insulation layer within the seventh via V7 are etched away to expose a surface of the second region of the sixth active layer (also the second region of the seventh active layer), and the seventh via V7 is configured such that a fifth connection electrode 55 formed subsequently is connected with the second region of the sixth active layer (also the second region of the seventh active layer) through this via V7.

In an exemplary implementation, an orthographic projection of the eighth via V8 on the substrate is within a range of an orthographic projection of the first region of the seventh active layer on the substrate. A sixth insulation layer, a fifth insulation layer, a fourth insulation layer, a third insulation layer, and a second insulation layer within the eighth via V8 are etched away to expose a surface of the first region of the seventh active layer, and the eighth via V8 is configured such that the second initial signal line formed subsequently is connected with the first region of the seventh active layer through this via V8.

In an exemplary implementation, an orthographic projection of the ninth via V9 on the base substrate is within a range of an orthographic projection of the first region of the eighth active layer on the base substrate, the sixth insulating layer, the fifth insulating layer, the fourth insulating layer, the third insulating layer and the second insulating layer within the ninth via V9 are etched away to expose a surface of the first region of the eighth active layer, and the ninth via V9 is configured such that a subsequently formed third initial signal line is connected to the first region of the eighth active layer through the via V9.

In an exemplary implementation, an orthographic projection of the tenth via V10 on the base substrate is within a range of an orthographic projection of the second region of the eighth active layer on the base substrate, the sixth insulating layer, the fifth insulating layer, the fourth insulating layer, the third insulating layer and the second insulating layer within the tenth via V10 are etched away to expose a surface of the second region of the eighth active layer, and the tenth via V10 is configured such that a subsequently formed second connection electrode is connected to the second region of the eighth active layer through the via V10.

In an exemplary implementation, an orthographic projection of the eleventh via V11 on the base substrate is within a range of the orthographic projection of the opening 83 on the base substrate. A sixth insulation layer, a fifth insulation layer, a fourth insulation layer and a third insulation layer within the eleventh via V11 are etched away to expose a surface of the first electrode plate 31, and the eleventh via V11 is configured such that the first connection electrode formed subsequently is connected with the first electrode plate 31 through this via V11.

In an exemplary implementation, an orthographic projection of the twelfth via V12 on the base substrate is within a range of an orthographic projection of the second electrode plate connection line 85 on the base substrate, the sixth insulation layer, the fifth insulation layer and the fourth insulation layer within the twelfth via V12 is etched away to expose a surface of the second electrode plate connection line 85, and the twelfth via V12 is configured such that a fourth connection electrode formed subsequently is connected with the second electrode plate connection line 85 through the via V12.

In an exemplary implementation, a part of two circuit units adjacent in the first direction X may share the same twelfth via V12. For example, two circuit units of the (N−1)th unit column and the Nth unit column may share the same twelfth via V12. As another example, two circuit units of the (N+1)th unit column and the (N+2)th unit column may share the same twelfth via V12. For another example, two circuit units of the (N+3)th unit column and the (N+4)th unit column may share the same twelfth via V12.

In an exemplary implementation, an orthographic projection of the thirteenth via V13 on the base substrate is within a range of an orthographic projection of a first end 33A of the first initial connection electrode 33 on the base substrate. A sixth insulation layer within the thirteenth via V13 is etched away to expose a surface of the first end 33A, and the thirteenth via V13 is configured such that the second initial connection electrode formed subsequently is connected to the first end 33A through the via V13.

In an exemplary implementation, an orthogonal projection of the fourteenth via V14 on the base substrate is within the range of an orthogonal projection of a second end 33B of the first initial connection electrode 33 on the base substrate. A sixth insulating layer within the fourteenth via V14 is etched away to expose the surface of the second end 33B, and the fourteenth via V14 is configured such that the second initial connection electrode formed subsequently is connected to the second end 33B through the via V14.

In an exemplary implementation, a plurality of vias in the at least one circuit unit may also include a fifteenth via V15, a sixteenth via V16, and a seventeenth via V17.

In an exemplary implementation, the fifteenth via V15 may be provided in the circuit units of the Nth unit column and the (N+3)th unit column, an orthogonal projection of the fifteenth via V15 on the base substrate is within the range of an orthogonal projection of the first connection block 33-1 of the first initial connection electrode 33 on the base substrate, a sixth insulating layer within the fifteenth via V15 is etched away to expose the surface of the first connection block 33-1, and the fifteenth via V15 is configured such that the first initial signal line formed subsequently is connected to the first connection block 33-1 through the via V15.

In an exemplary implementation, the sixteenth via V16 may be provided in circuit units of the (N+1)th unit column, an orthographic projection of the sixteenth via V16 on the base substrate is within the range of the orthographic projection of the second connection block 33-2 of the first initial connection electrode 33 on the base substrate, a sixth insulating layer within the sixteenth via V16 is etched away to expose the surface of the second connection block 33-2, and the sixteenth via V16 is configured such that the second initial signal line formed subsequently is connected to the second connection block 33-2 through the via V16.

In an exemplary implementation, the seventeenth via V17 may be provided in the circuit units of the (N+2)th unit column, an orthographic projection of the seventeenth via V17 on the base substrate is within the range of an orthographic projection of the third connection block 33-3 of the first initial connection electrode 33 on the base substrate, a sixth insulating layer in the seventeenth via V17 is etched away to expose the surface of the third connection block 33-3, and the sixteenth via V16 is configured such that the third initial signal line formed subsequently is connected to the third connection block 33-3 through the via V17.

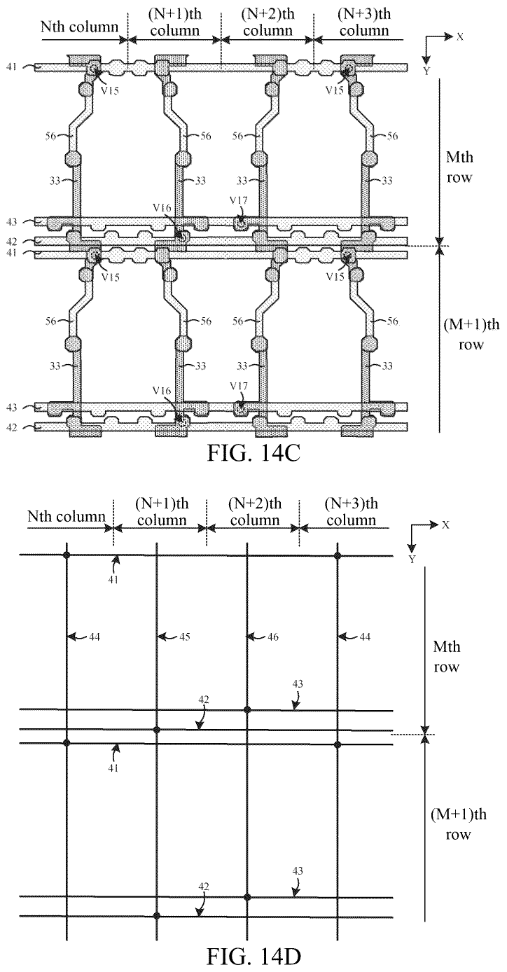

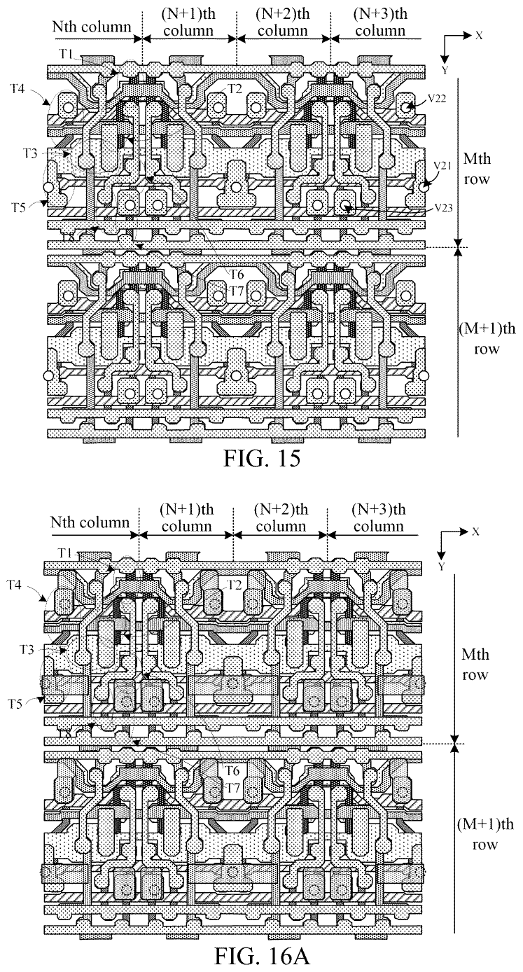

(7) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film through a patterning process to form the fourth conductive layer disposed on the sixth insulation layer, as shown in FIG. 14A and FIG. 14B, and FIG. 14B is a schematic plan view of the fourth conductive layer in FIG. 14A. In an exemplary implementation, the fourth conductive layer may be referred to as a first source drain metal (SD1) layer.

In an exemplary implementation, the fourth conductive layer in each circuit unit includes at least a first initial signal line 41, a second initial signal line 42, a third initial signal line 43, a first connection electrode 51, a second connection electrode 52, a third connection electrode 53, a fourth connection electrode 54, a fifth connection electrode 55, and a second initial connection electrode 56.

In an exemplary implementation, a shape of the first connection electrode 51 may be a strip shape extending along the second direction Y, a first end of the first connection electrode 51 is connected with the second region of the second active layer through the third via V3, and a second end of the first connection electrode 51 is connected with the first electrode plate 31 through the eleventh via V11. In an exemplary implementation, since the first electrode plate 31 simultaneously serves as the gate electrode of the third transistor T3, the first connection electrode 51 enables the second electrode of the second transistor T2, the gate electrode of the third transistor T3 and the first electrode plate 31 to have a same potential to form a first node N1 of the pixel drive circuit. In an exemplary implementation, the first connection electrode 51 may be referred to as the first node electrode.

In an exemplary implementation, an orthographic projection of the first connection electrode 51 on the base substrate is at least partially overlapped with the orthographic projection of the first scan signal line 21 on the base substrate. Since the first connection electrode 51 serves as the first node N1 of the pixel drive circuit, the first connection electrode 51 can increase a parasitic capacitance between the first scan signal line 21 and the first node N1. In an exemplary implementation, after the fourth scan signal line 24 outputs a turned-on signal, the parasitic capacitance can pull down the potential of the first node N1 by using the falling edge of the first scan signal line 21, thereby increasing the current and effectively improving the display brightness.

In an exemplary implementation, a first compensation block 51-1 may be provided on the first connection electrode 51, a first end of the first compensation block 51-1 is connected to a first end of the first connection electrode 51, a second end of the first compensation block 51-1 extends towards the direction of the first scan signal line 21, and an orthographic projection of the first compensation block 51-1 on the base substrate is at least partially overlapped with the orthographic projection of the first scan signal line 21 on the base substrate.

In an exemplary implementation, the first connection electrode 51 and the first compensation block 51-1 may be an integrated structure connected to each other.

In an exemplary implementation, the shape of the second connection electrode 52 may be a strip shape in which the main body portion extends in the second direction Y. A first end of the second connection electrode 52 is connected to the second region of the first active layer (it is also the first region of the second active layer) through the second via V2, the third via V3 is connected to the second region of the second active layer. A second end of the second connection electrode 52 is connected to the second region of the eighth active layer through the tenth via V10, and a region between the first and second ends of the second connection electrode 52 is connected to the second region of the third active layer (it is also the first region of the sixth active layer) through the fourth via V4. In an exemplary implementation, the second connection electrode 52 enables the second electrode of the first transistor T1, the first electrode of the second transistor T2, the second electrode of the third transistor T3, the first electrode of the sixth transistor T6 and the second electrode of the eighth transistor T8 to have a same potential to form a second node N2 of the pixel drive circuit. In an exemplary implementation, the second connection electrode 52 may be referred to as a second node electrode.

In an exemplary implementation, in the region where the second via V2 is located, a curved portion is provided on the fourth scan signal line 24, and the curved portion protrudes towards a direction away from the second electrode plate 82, so that the fourth scan signal line 24 can avoid the second connection electrode 52, and the orthographic projection of the second connection electrode 52 on the base substrate is not overlapped with the orthographic projection of the fourth scan signal line 24 on the base substrate. Since the second connection electrode 52 is used as the second node N2 of the pixel drive circuit, the parasitic capacitance between the second node N2 and the fourth scan signal line 24 can be effectively reduced. On the one hand, the parasitic capacitance of the second node N2 can be reduced, and on the other hand, the influence on the data signal write process can be reduced.

In an exemplary implementation, the fourth scan signal line 24 is provided with a bend portion that avoids the second connection electrode 52, and the third scan signal line 23 is provided with a bend portion that avoids the first initial connection electrode 33, such that the orthographic projection of the fourth scan signal line 24 on the base substrate and the orthographic projection of the third scan signal line 23 on the base substrate are overlapped at least partially, resulting in an increased parasitic capacitance between the third scan signal line 23 and the fourth scan signal line 24. Since the third scan signal line 23 outputs a turned-on signal in a second period, the turned-on signal does not affect the fourth scan signal line 24 to output the turned-on signal in a third period, nor does it affect the data signal write process.

In an exemplary implementation, the orthographic projection of the second connection electrode 52 on the base substrate is not overlapped with the orthographic projection of the first sub-scan line segment 21-1 in the first scan signal line 21 on the base substrate, the orthographic projection of the second connection electrode 52 on the base substrate is not overlapped with the orthographic projection of the first sub-shielding line segment 31-1 in the first shielding line 31 on the base substrate, the orthographic projection of the second connection electrode 52 on the base substrate is at least partially overlapped with the orthographic projection of the second sub-scan line segment 21-2 in the first scan signal line 21 on the base substrate, and the orthographic projection of the second connection electrode 52 on the base substrate is at least partially overlapped with the orthographic projection of the second sub-shielding line segment 31-2 in the first shielding line 31 on the base substrate. Since the width of the second sub-shielding line segment 31-2 is less than the width of the first sub-shielding line segment 31-1, and the width of the second sub-scan line segment 21-2 is less than the width of the first sub-scan line segment 21-1, the parasitic capacitance between the second connection electrode 52 and the first scan signal line 21 (the first shielding line 31) can be effectively reduced. On the one hand, the parasitic capacitance of the second node N2 can be reduced, and on the other hand, the influence on the first scan signal line can be reduced.

In an exemplary implementation, the shape of the third connection electrode 53 may be a block shape (such as a rectangle), the third connection electrode 53 is connected to the first region of the fourth active layer through the fifth via V5, and the third connection electrode 53 is configured to be connected to the twelfth connection electrode formed subsequently.

In an exemplary implementation, the shape of the fourth connection electrode 54 may be a strip shape extending in the second direction Y, a first end of the fourth connection electrode 54 is connected to the first region of the fifth active layer through the sixth via V6, a second end of the fourth connection electrode 54 is connected to the second electrode plate connection line 85 through the twelfth via V12, and the fourth connection electrode 54 is configured to be connected to the eleventh connection electrode formed subsequently. In an exemplary implementation, since the second electrode plate connection line 85 is connected to the second electrode plate 82, with the fourth connection electrode 54, the first electrode of the fifth transistor T5 in the circuit unit and the second electrode 82 of the storage capacitance have the same potential.

In an exemplary implementation, a part of the fourth connection electrodes 54 of the two circuit units adjacent in the first direction X may be an integrated structure connected to each other. For example, the fourth connection electrodes 54 of the two circuit units of the (N−1)th unit column and the Nth unit column may be an integrated structure connected to each other. As another example, the fourth connection electrodes 54 of the two circuit units of the (N+1)th unit column and the (N+2)th unit column may be an integrated structure connected to each other. For another example, the fourth connection electrodes 54 of the two circuit units of the (N+3)th unit column and the (N+4)th unit column may be an integrated structure connected to each other.

In an exemplary implementation, the fifth connection electrode 55 may be in a shape of a block (such as a rectangle), and the fifth connection electrode 55 is connected to the second region of the sixth active layer (also the second region of the seventh active layer) through the seventh via V7. In an exemplary implementation, the fifth connection electrode 55 is configured to be connected to a thirteenth connection electrode subsequently formed to form a fourth node N4 of the pixel drive circuit.

In an exemplary implementation, the shape of the second initial connection electrode 56 may be a bending line in which the main body portion extends in the second direction Y, a first end of the second initial connection electrode 56 is connected to the first end 33A of the first initial connection electrode 33 through the thirteenth via V13, and a second end of the second initial connection electrode 56 is connected to the second end 33B of the first initial connection electrode 33 through the fourteenth via V14.

In an exemplary implementation, the shape of the first initial signal line 41 may be a straight line or a bending line extending in the first direction X, and may be provided on a side of the third scan signal line 23 away from the second electrode plate 82. In each circuit unit, the first initial signal line 41 is connected to the first region of the first active layer through the first via V1, realizing the connection of the first initial signal line 41 with the first electrode of the first transistor T1, and the first initial signal line 41 can write the transmitted first initial signal to the first electrode of the first transistor T1.

In an exemplary implementation, in the circuit units of the Nth unit column and the (N+3)th unit column, the first initial signal line 41 is also connected to the first connection block 33-1 through the fifteenth via V15. Since the first connection block 33-1 is connected to the first initial connection electrode 33, the first initial connection electrodes 33 of adjacent unit rows are connected to each other through the second initial connection electrode 56, and the first initial connection electrodes 33 and the second initial connection electrodes 56 connected to each other in the Nth unit column and the (N+3)th unit column form first initial connection lines. The connection of the first initial signal line 41 extending along the first direction X with the first initial connection line extending along the second direction Y is realized, so that the first initial signal lines 41 and the first initial connection lines form a mesh structure for transmitting the first initial signal in the display area, not only the resistance of the first initial signal line can be reduced effectively, the voltage drop of the first initial signal can be reduced, but also the uniformity of the first initial signal in the display substrate can be improved effectively, the uniformity of the display can be improved effectively, and the display quality is improved.

In an exemplary implementation, the shape of the second initial signal line 42 may be a straight line or a bending line extending in the first direction X, and may be provided on a side of the second scan signal line 22 away from the second electrode plate 82. In each circuit unit, the second initial signal line 42 is connected to the first region of the seventh active layer through the eighth via V8, thereby realizing the connection of the second initial signal line 42 with the first electrode of the seventh transistor T7, and the second initial signal line 42 can write the transmitted second initial signal to the first electrode of the seventh transistor T7.

In an exemplary implementation, in the circuit units in the (N+1)th unit column, the second initial signal line 42 is also connected to the second connection block 33-2 through the sixteenth via V16. Since the second connection block 33-2 is connected to the first initial connection electrode 33, the first initial connection electrodes 33 of adjacent unit rows are connected to each other through the second initial connection electrode 56, and the first initial connection electrodes 33 and the second initial connection electrode 56 connected to each other in the (N+1)th unit column form a second initial connection line. The connection of the second initial signal line 42 extending along the first direction X with the second initial connection line extending along the second direction Y is realized, so that the second initial signal lines 42 and the second initial connection lines form a mesh structure for transmitting the second initial signal in the display area, not only the resistance of the second initial signal line can be reduced effectively, the voltage drop of the second initial signal can be reduced, but also the uniformity of the second initial signal in the display substrate can be improved effectively, the uniformity of the display can be improved effectively, and the display quality is improved.

In an exemplary implementation, the shape of the third initial signal line 43 may be a straight line or a bending line extending in the first direction X, and may be provided between the second scan signal line 22 and the second initial signal line 42. In each circuit unit, the third initial signal line 43 is connected to the first region of the eighth active layer through the ninth via V9, thereby realizing the connection of the third initial signal line 43 with the first electrode of the eighth transistor T8, and the third initial signal line 43 can write the transmitted second initial signal to the first electrode of the eighth transistor T8.

In an exemplary implementation, in the circuit units in the (N+2)th unit column, the third initial signal line 43 is also connected to the third connection block 33-3 through the seventeenth via V17. Since the third connection block 33-3 is connected to the first initial connection electrode 33, the first initial connection electrodes 33 of adjacent unit rows are connected to each other through the second initial connection electrode 56, and the first initial connection electrodes 33 and the second initial connection electrode 56 connected to each other in the (N+2)th unit column form a third initial connection line. The connection of the third initial signal line 43 extending along the first direction X with the third initial connection line extending along the second direction Y is realized, so that the third initial signal lines 43 and the third initial connection lines form a mesh structure for transmitting the third initial signal in the display area, not only the resistance of the third initial signal line can be reduced effectively, the voltage drop of the third initial signal can be reduced, but also the uniformity of the third initial signal in the display substrate can be improved effectively, the uniformity of the display can be improved effectively, and the display quality is improved.

FIGS. 14C and 14D are schematic diagrams of initial signal lines of a mesh structure in FIG. 14A. As shown in FIGS. 14C and 14D, the first initial signal line 41, the second initial signal line 42, and the third initial signal line 43 may be provided in each unit row, a first initial connection line 44 may be provided in the Nth unit column and the (N+3)th unit column, a second initial connection line 45 may be provided in the (N+1)th unit column, and a third initial connection line 46 may be provided in the (N+2)th unit column. The initial connection line in each unit column is composed of the first initial connection electrode 33 and the second initial connection electrode 56 connected to each other. The first initial connection electrode 33 and the second initial connection electrode 56 are provided in different conductive layers, and the two are connected to each other through a via.

In an exemplary implementation, the first initial connection lines 44 located in the Nth unit column and the (N+3)th unit column are connected to the first initial signal lines 41 in the plurality of circuit units through the fifteenth vias V15 in the plurality of circuit units, thereby forming a mesh structure for transmitting the first initial signal in the display area.

In an exemplary implementation, the second initial connection line 45 located in the (N+1)th unit column is connected to the second initial signal lines 42 in the plurality of circuit units through the sixteenth vias V16 in the plurality of circuit units, thereby forming a mesh structure for transmitting the second initial signal in the display area.

In an exemplary implementation, the third initial connection line 46 located in the (N+2)th unit column is connected to the third initial signal lines 43 in the plurality of circuit units through the seventeenth vias V17 in the plurality of circuit units, thereby forming a mesh structure for transmitting the third initial signal in the display area.

In an exemplary implementation, the first initial connection lines 44, the second initial connection lines 45 and the third initial connection lines 46 may be periodically provided in a plurality of unit columns, the second initial connection line 45 and the third initial connection line 46 are provided between two adjacent first initial connection lines 44, the first initial connection line 44 and the third initial connection line 46 are provided between two adjacent second initial connection lines 45, and the first initial connection line 44 and the second initial connection line 45 are provided between two adjacent third initial connection lines 46.

In an exemplary implementation, the first initial connection lines 44, the second initial connection lines 45, and the third initial connection lines 46 may be arranged in a plurality of unit columns in a variety of modes. For example, two first initial connection lines 44 may be provided in adjacent two unit columns, two second initial connection lines 45 may be provided in other adjacent two unit columns, and two third initial connection lines 46 may be provided in further other adjacent two unit columns, which is not defined in present disclosure.

(8) A pattern of a first planarization layer is formed. In an exemplary implementation, forming the pattern of the first planarization layer may include: coating a first planarization thin film on the base substrate on which the aforementioned patterns are formed, patterning the first planarization thin film using a patterning process to form a first planarization layer covering the pattern of the fourth conductive layer, herein the first planarization layer is provided with a plurality of vias, as shown in FIG. 15.

In an exemplary implementation, the plurality of vias in each circuit unit at least includes a twenty-first via V21, a twenty-second via V22, and a twenty-third via V23.

In an exemplary implementation, an orthographic projection of the twenty-first via V21 on the base substrate is located within a range of an orthographic projection of the fourth connection electrode 54 on the base substrate, the first planarization layer within the twenty-first via V21 is etched away to expose a surface of the fourth connection electrode 54, and the twenty-first via V21 is configured such that an eleventh connection electrode formed subsequently is connected with the fourth connection electrode 54 through the via V21.

In an exemplary implementation, a part of two circuit units adjacent in the first direction X may share the same twenty-first via V21. For example, two circuit units of the (N−1)th unit column and the Nth unit column may share the same twenty-first via V21. As another example, two circuit units of the (N+1)th unit column and the (N+2)th unit column may share the same twenty-first via V21. For another example, two circuit units of the (N+3)th unit column and the (N+4)th unit column may share the same twenty-first via V21.

In an exemplary implementation, an orthographic projection of the twenty-second via V22 on the base substrate is within a range of an orthographic projection of the third connection electrode 53 on the base substrate, a first planarization layer within the twenty-second via V22 is etched away to expose a surface of the third connection electrode 53, and the twenty-second via V22 is configured such that a twelfth connection electrode formed subsequently is connected with the third connection electrode 53 through the via V22.

In an exemplary implementation, an orthographic projection of the twenty-third via V23 on the base substrate is within a range of an orthographic projection of the fifth connection electrode 55 on the base substrate, a first planarization layer in the twenty-third via V23 is etched away to expose a surface of the fifth connection electrode 55, and the twenty-third via V23 is configured such that the thirteen connection electrode formed subsequently is connected to the fifth connection electrode 55 through the twenty-third via V23.

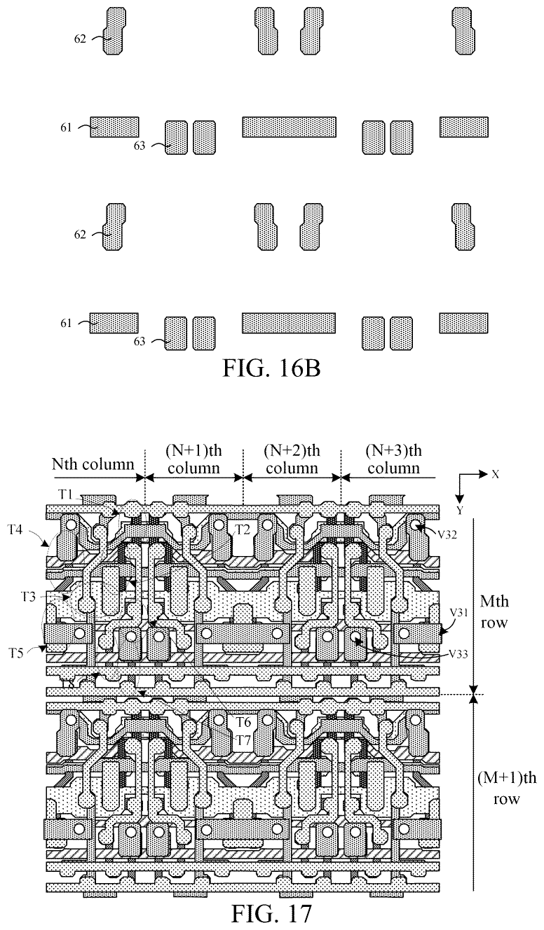

(9) A pattern of a fifth conductive layer is formed. In an exemplary implementation, forming the pattern of the fifth conductive layer may include: depositing a fifth conductive thin film on the base substrate on which the aforementioned patterns are formed, and patterning the fifth conductive thin film using a patterning process to form the fifth conductive layer disposed on the first planarization layer, as shown in FIG. 16A and FIG. 16B, and FIG. 16B is a schematic plan view of the fifth conductive layer in FIG. 16A. In an exemplary implementation, the fifth conductive layer may be referred to as a second source-drain metal (SD2) layer.

In an exemplary implementation, a fifth conductive layer of each circuit unit at least includes an eleventh connection electrode 61, a twelfth connection electrode 62, and a thirteen connection electrode 63.

In an exemplary implementation, the eleventh connection electrode 61 may be in the shape of a strip extending along the first direction X. The eleventh connection electrode 61 may be connected to the fourth connection electrode 54 through the twenty-first via V21. The eleventh connection electrode 61 is configured to be connected to the first power supply line formed subsequently.

In an exemplary implementation, a part of the eleventh connection electrodes 61 of two circuit units adjacent in the first direction X may be an integrated structure connected to each other. For example, the eleventh connection electrodes 61 of the two circuit units of the (N−1)th unit column and the Nth unit column may be an integrated structure connected to each other. As another example, the eleventh connection electrodes 61 of the two circuit units of the (N+1)th unit column and the (N+2)th unit column may be an integrated structure connected to each other. As a further example, the eleventh connection electrodes 61 of the two circuit units of the (N+3)th unit column and the (N+4)th unit column may be an integrated structure connected to each other.

In an exemplary implementation, a shape of the eleventh connection electrode 62 may be a block shape (such as a rectangular shape). The twelfth connection electrode 62 may be connected with the third connection electrode 53 through the twenty-second via V22. The twelfth connection electrode 62 is configured to be connected with a data signal line formed subsequently.

In an exemplary implementation, a shape of the thirteen connection electrode 63 may be a block shape (such as a rectangular shape). The thirteen connection electrode 63 may be connected with the fifth connection electrode 55 through the twenty-third via V23. The thirteen connection electrode 63 is configured to be connected with an anode connection electrode formed subsequently.

(10) A pattern of a second planarization layer is formed. In an exemplary implementation, forming the pattern of the second planarization layer may include: coating a second planarization thin film on the base substrate on which the aforementioned patterns are formed, patterning the second planarization thin film using a patterning process to form the second planarization layer covering a pattern of the fifth conductive layer, herein a plurality of vias are provided on the second planarization layer, as shown in FIG. 17.

In an exemplary implementation, a plurality of vias in each circuit unit at least include a thirty-first via V31, a thirty-second via V32, and a thirty-third via V33.

In an exemplary implementation, an orthographic projection of the thirty-first via V31 on the base substrate is within a range of an orthographic projection of the eleven connection electrode 61 on the base substrate. A second planarization layer in the thirty-first via V31 is etched away to expose a surface of the eleven connection electrode 61. The thirty-first via V31 is configured such that a first power supply line formed subsequently is connected with the eleven connection electrode 61 through the via V31.

In an exemplary implementation, an orthographic projection of the thirty-second via V32 on the base substrate is within a range of an orthographic projection of the twelfth connection electrode 62 on the base substrate, the second planarization layer within the thirty-second via V32 is etched away to expose a surface of the twelfth connection electrode 62, and the thirty-second via V32 is configured such that an data signal line formed subsequently is connected with the twelfth connection electrode 62 through the via V32.

In an exemplary implementation, an orthographic projection of the thirty-third via V33 on the base substrate is within a range of an orthographic projection of the thirteen connection electrode 63 on the base substrate, the first planarization layer in the thirty-third via V33 is etched away to expose a surface of the thirteen connection electrode 63, and the thirty-third via V33 is configured such that the anode connection electrode formed subsequently is connected with the thirteen connection electrode 63 through the thirty-third via V33.

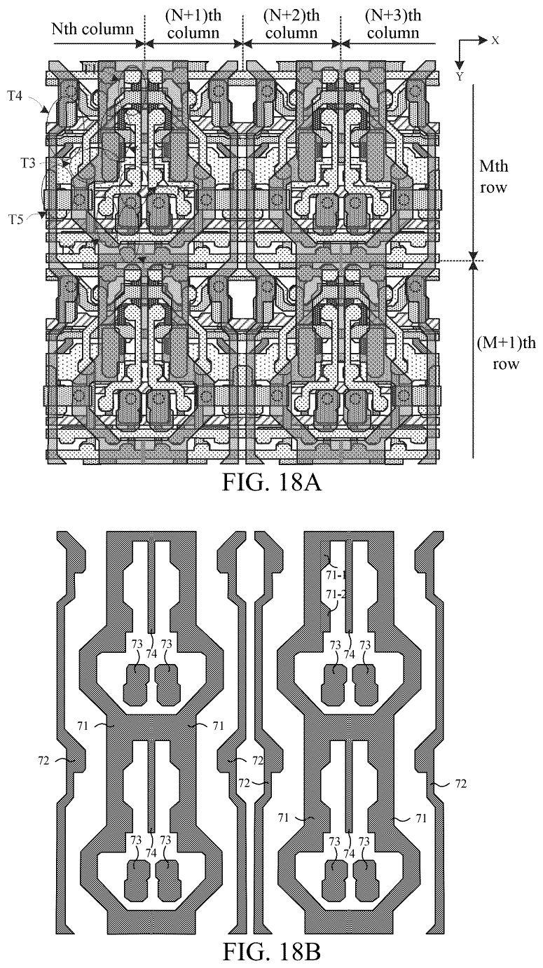

(11) A pattern of a sixth conductive layer is formed. In an exemplary implementation, forming the pattern of the sixth conductive layer may include: depositing a sixth conductive thin film on the base substrate on which the aforementioned patterns are formed, and patterning the sixth conductive thin film using a patterning process to form the sixth conductive layer disposed on the second planarization layer, as shown in FIG. 18A and FIG. 18B, and FIG. 18B is a schematic plan view of the sixth conductive layer in FIG. 18A. In an exemplary implementation, the sixth conductive layer may be referred to as a third source-drain metal (SD3) layer.

In an exemplary implementation, the sixth conductive layer of each circuit unit includes at least a first power supply line 71, a data signal line 72 and an anode connection electrode 73.

In an exemplary implementation, the first power supply line 71 may be in a shape of a straight line or a bending line in which a main portion extends in the second direction Y, and the first power supply line 71 is connected to the eleven connection electrode 61 through the thirty-first via V31. Since the eleventh connection electrode 61 is connected to the fourth connection electrode 54, and the fourth connection electrode 54 is connected to the first electrode of the fifth transistor T5 and the second electrode plate 82 of the storage capacitance, respectively, the first power supply signal can be written to the fifth transistor T5 and the second electrode plate 82 of the storage capacitance with the first power supply line 71.

In an exemplary implementation, the first power supply line 71 may be a bending line of unequal width, which may not only facilitate a layout of a pixel structure, but also reduce a parasitic capacitance between the first power supply line and a data signal line.

In an exemplary implementation, a part of the first power supply lines 71 of two circuit units adjacent in the first direction X may be an integrated structure connected to each other. For example, the first power supply lines 71 of the two circuit units of the (N−1)th unit column and the Nth unit column may be an integrated structure connected to each other. As another example, the first power supply lines 71 of the two circuit units of the (N+1)th unit column and the (N+2)th unit column may be an integrated structure connected to each other. As a further example, the first power supply lines 71 of the two circuit units of the (N+3)th unit column and the (N+4)th unit column may be an integrated structure connected to each other.

In an exemplary implementation, an orthographic projection of the first power supply line 71 on the base substrate is at least partially overlapped with an orthographic projection of the first connection electrode 51 on the base substrate, and the first power supply line 71 with a constant potential can effectively shield the influence of the data voltage jump and other signals on the first node N1 in the pixel drive circuit, avoid the influence of the data voltage jump and other signals on the potential of the first node N1, and improve the driving performance of the pixel drive circuit.

In an exemplary implementation, the orthographic projection of the first power supply line 71 on the base substrate includes the orthographic projection of the first connection electrode 51 on the base substrate, that is, the first power supply line 71 completely covers the first connection electrode 51.

In an exemplary implementation, the orthographic projection of the first power supply line 71 on the base substrate is at least partially overlapped with the orthographic projection of the second active layer on the base substrate. In an exemplary implementation, the first power supply line 71 can prevent light emitted from the light emitting device and reflected light from the film layer from irradiating the oxide second transistor, and can prevent the oxide second transistor from undergoing characteristic drift due to the irradiation of light, thereby improving the electrical characteristics of the oxide second transistor.

In an exemplary implementation, the orthographic projection of the first power supply line 71 on the base substrate is not overlapped with the orthographic projection of the second connection electrode 52 on the base substrate, and the parasitic capacitance of the second node N2 can be effectively reduced.

In an exemplary implementation, a shield electrode 74 is provided on the first power supply line 71, the shape of the shield electrode 74 may be a strip shape extending in the second direction Y, a first end of the shield electrode 74 is connected to the first power supply line 71, and a second end of the shield electrode 74 extends in the direction of the anode connection electrode 73 in the circuit unit.

In an exemplary implementation, the shield electrode 74 may be provided in the middle of the first power supply line 71 of the integrated structure, and the first power supply line 71 of the integrated structure may be substantially mirror-symmetrical with respect to the shield electrode 74.

In an exemplary implementation, an orthographic projection of the shield electrode 74 on the base substrate is not overlapped with the orthographic projection of the second connection electrode 52 on the base substrate to effectively reduce the parasitic capacitance of the second node N2.

In an exemplary implementation, in the first direction X, part of the shield electrodes 74 may be disposed between part of the second connection electrodes 52 adjacent to each other, and the shield electrode 74 having a constant potential may effectively reduce the mutual influence of the second nodes N2 in adjacent circuit units, thereby improving the driving performance of the pixel drive circuit. For example, the shield electrode 74 may be provided between the second connection electrode 52 of the circuit unit in the Nth unit column and the second connection electrode 52 of the circuit unit in the (N+1) unit column. As another example, the shield electrode 74 may be provided between the second connection electrode 52 of the circuit unit in the (N+2)th unit column and the second connection electrode 52 of the circuit unit in the (N+3)th unit column.

In an exemplary implementation, the shield electrode 74 is also configured to improve the flatness of the anode.

In an exemplary implementation, the first power supply line 71 may also be provided with a first power supply block 71-1 and a second power supply block 71-2. The first power supply block 71-1 and the second power supply block 71-2 may be in the shape of a block (such as a trapezoid), and may be provided on a side of the first power supply line 71 close to the shield electrode 74, and correspond to two ends of the shield electrode 74, respectively. In an exemplary implementation, the first power supply block 71-1 and the second power supply block 71-2 are configured to improve the flatness of the anode.

The first power supply line 71, the first power supply block 71-1, the second power supply block 71-2, and the shield electrode 74 may be an integrated structure connected to each other.

In an exemplary implementation, the data signal line 72 may be in a shape of a straight line or a bending line whose main portion extends along the second direction Y, and the data signal line 72 is connected to the twelfth connection electrode 62 through the thirty-second via V32. Since the twelfth connection electrode 62 is connected to the third connection electrode 53, and the third connection electrode 53 is connected to the first region of the fourth active layer through a via, a connection between the data signal line 72 and the first electrode of the fourth transistor T4 is achieved, and the data signal line 72 can write a data signal to the first electrode of the fourth transistor T4.

In an exemplary implementation, the anode connection electrode 73 may be in a shape of a block (e.g., a rectangle), the anode connection electrode 73 is connected to the thirteen connection electrode 63 through the thirty-third via V33, and the anode connection electrode 73 is configured to be connected to an anode formed subsequently. Since the anode connection electrode 73 is connected with the fifth connection electrode 55, and the fifth connection electrode 55 is connected with the second region of the sixth active layer and the second region of the seventh active layer through a via, a connection between the anode formed subsequently, and the second electrode of the sixth transistor T6 and the second electrode of the seventh transistor T7 may be achieved, and the pixel drive circuit may drive a light emitting device to emit light.

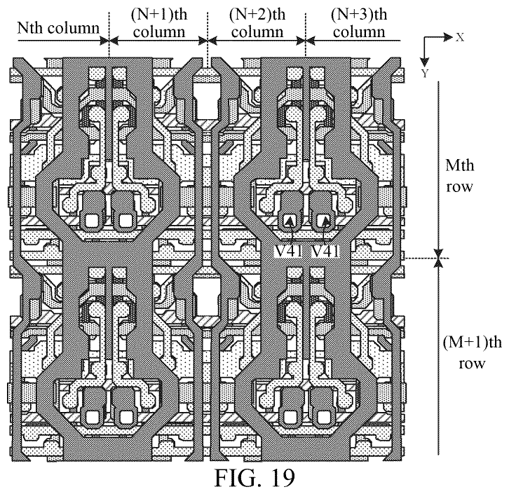

(12) A pattern of a third planarization layer is formed. In an exemplary implementation, forming the pattern of the third planarization layer may include: coating a third planarization thin film on the base substrate on which the aforementioned patterns are formed, patterning the third planarization thin film using a patterning process to form a third planarization layer covering the pattern of the sixth conductive layer, herein the third planarization layer is provided with a plurality of vias, as shown in FIG. 19.

In an exemplary implementation, vias in each circuit unit at least include a forty-first via V41.

In an exemplary implementation, an orthographic projection of the forty-first via V41 on the base substrate is within a range of an orthographic projection of the anode connection electrode 73 on the base substrate, the third planarization layer within the forty-first via V41 is removed to expose a surface of the anode connection electrode 73, and the forty-first via V41 is configured such that an anode formed subsequently is connected with the anode connection electrode 73 through the via V41.

So far, a drive circuit layer has been manufactured on the base substrate. In a plane parallel to the display substrate, the drive circuit layer may include a plurality of circuit units, each circuit unit may include a pixel drive circuit, and a first scan signal line, a second scan signal line, a third scan signal line, a fourth scan signal line, a light emitting control line, a first initial signal line, a second initial signal line, a third initial signal line, a data signal line and a first power supply line which are connected to the pixel drive circuit. In a direction perpendicular to the display substrate, the drive circuit layer may include a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, a second planarization layer, a sixth conductive layer, and a third planarization layer disposed sequentially on the base substrate. The first semiconductor layer may include at least active layers of the third transistor to the eighth transistor, the first conductive layer may include at least the second scan signal line, the fourth scan signal line and a first electrode plate of storage capacitance, the second conductive layer may include at least a second electrode plate of the storage capacitance, the second semiconductor layer may include at least active layers of the first transistor and the second transistor, the third conductive layer may include at least the first scan signal line and the third scan signal line, the fourth conductive layer may include a plurality of connection electrodes, the fifth conductive layer may include at least a plurality of connection electrodes, the sixth conductive layer may include at least a data signal line, the first power supply line and the anode connection electrode.

In an exemplary implementation, the base substrate may be a flexible substrate, or a rigid substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible base substrate may include a first flexible material layer, a first inorganic material layer, a semiconductor layer, a second flexible material layer and a second inorganic material layer stacked on the glass carrier plate. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, multiple layers, or a composite layer. The first insulating layer may be referred to as a buffer layer, the second insulating layer, the third insulating layer, the fourth insulating layer and the fifth insulating layer may be referred to as a gate insulating (GI) layer, the sixth insulating layer may be referred to as an interlayer dielectric (ILD) layer, and the seventh insulating layer may be referred to as a passivation (PVX) layer. The first planarization layer, the second planarization layer, and the third planarization layer may be made of an organic material, such as a resin.

In an exemplary implementation, pixel drive circuits in two adjacent circuit units in a unit row may be substantially mirror-symmetrical with respect to a column centerline. For example, the pixel drive circuits of the Nth column and the pixel drive circuits of the (N+1)th column may be mirror-symmetrical with respect to a column centerline. For another example, the pixel drive circuits of the (N+1)th column and the pixel drive circuits of the (N+2)th column may be mirror-symmetrical with respect to a column centerline.

In an exemplary implementation, after the drive circuit layer is prepared, a light emitting structure layer may be prepared on the drive circuit layer, and the preparation process of the light emitting structure layer may include the following operations.

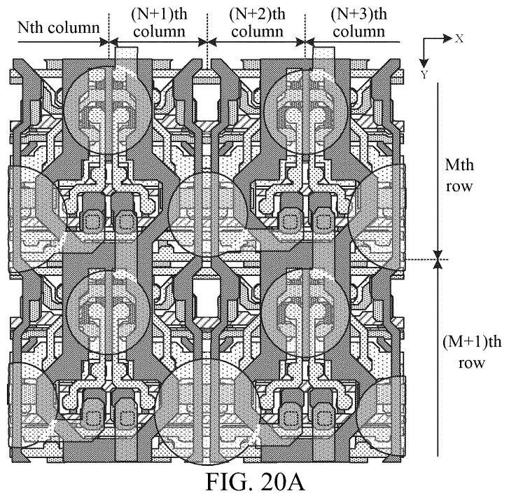

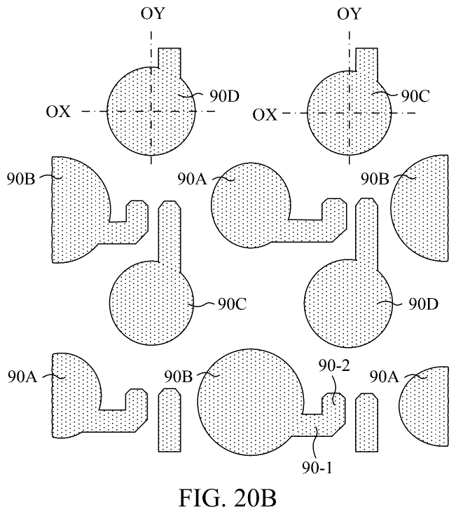

(13) A pattern of an anode conductive layer is formed. In an exemplary implementation, forming a pattern of an anode conductive layer may include: depositing an anode conductive thin film on the base substrate on which the aforementioned patterns are formed, and patterning the anode conductive thin film through a patterning process to form an anode conductive layer disposed on the third planarization layer, herein the anode conductive layer may at least includes a plurality of anode patterns, as shown in FIG. 20A and FIG. 20B, and FIG. 20B is a planar schematic diagram of the anode conductive layer in FIG. 20A.

In an exemplary implementation, the plurality of anode patterns may include a first anode 90A of a red light emitting device, a second anode 90B of a blue light emitting device, a third anode 90C of a first green light emitting device, and a fourth anode 90D of a second green light emitting device, herein the first anode 90A may be located at a red sub-pixel emitting red light, the second anode 90B may be located at a blue sub-pixel emitting blue light, the third anode 90C may be located at a first green sub-pixel emitting green light, and the fourth anode 90D may be located at a second green sub-pixel emitting green light.

In an exemplary implementation, the first anode 90A and the second anode 90B may be sequentially disposed along the first direction X, the third anode 90C and the fourth anode 90D may be sequentially disposed along the first direction X, and the third anode 90C and the fourth anode 90D may be disposed on one side of the first anode 90A and the second anode 90B in the second direction Y, respectively. Or, the first anode 90A and the second anode 90B may be sequentially disposed along the second direction Y, the third anode 90C and the fourth anode 90D may be sequentially disposed along the second direction Y, and the third anode 90C and the fourth anode 90D may be disposed on one side of the first anode 90A and the second anode 90B in the first direction X.

In an exemplary implementation, the first anode 90A, the second anode 90B, the third anode 90C, and the fourth anode 90D may be respectively connected to the anode connection electrode 73 of a corresponding circuit unit through the forty-first via V41, and shapes and areas of the anodes of four sub-pixels in one pixel unit may be the same or may be different.

In an exemplary implementation, at least one of the first anode 90A, the second anode 90B, the third anode 90C, and the fourth anode 90D may include an anode main body and an anode connection portion connected to each other, the anode main body may be in a circular shape or an oval shape, the anode connection portion may be in a strip shape, and the anode connection portion is connected with the anode connection electrode 73 through the forty-first via V41, so that the anode can be connected to the second electrode of the sixth transistor T6 and the second electrode of the seventh transistor T7.

In an exemplary implementation, the anode main body portion and the anode connection portion of the at least one anode may be an integrated structure connected to each other.

In an exemplary implementation, the anode main body portion of the at least one anode may have a first anode centerline OX and a second anode centerline OY, herein the first anode centerline OX may be a straight line that bisects the anode main body portion of the anode in the second direction Y and extends along the first direction X, and the second anode centerline OY may be a straight line that bisects the anode main body portion of the anode in the first direction X and extends along the second direction Y. For example, the third anode 90C and the fourth anode 90D may each have a first anode centerline OX and a second anode centerline OY.

In an exemplary implementation, an orthographic projection of the anode main body portion of the at least one anode on the base substrate is at least partially overlapped with orthographic projections of the two first power supply lines 71 in two circuit units adjacent in the first direction X on the base substrate, and the two first power supply lines 71 may be mirror-symmetrical with respect to the second anode centerline OY of the anode.

In an exemplary implementation, the orthographic projection of the anode main body portion of the at least one anode on the base substrate is at least partially overlapped with orthographic projections of the first power supply block 71-1 and the second power supply block 71-2 of the at least one first power supply line 71 on the base substrate, for example, an orthographic projection of the anode main body portion of the third anode 90C on the base substrate is at least partially overlapped with orthographic projections of a first power supply block 71-1 and a second power supply block 71-2 of the first power supply line 71 on the base substrate. As another example, an orthographic projection of the anode main body portion of the fourth anode 90D on the base substrate is at least partially overlapped with orthographic projections of a first power supply block 71-1 and a second power supply block 71-2 of the other first power supply line 71 on the base substrate.

In an exemplary implementation, positions and shapes of the first power supply block 71-1 and the second power supply block 71-2 of the at least one first power supply line 71 may be substantially mirror-symmetrical with respect to the first anode centerline OX of the at least one anode. For example, positions and shapes of a first power supply block 71-1 and a second power supply block 71-2 of one first power supply line 71 are substantially mirror-symmetrical with respect to the first anode centerline OX of the third anode 90C. As another example, positions and shapes of a first power supply block 71-1 and a second power supply block 71-2 of the other first power supply line 71 are substantially mirror-symmetrical with respect to the first anode centerline OX of the fourth anode 90D.

In an exemplary implementation, in the at least one first power supply line 71, an orthographic projection of the first power supply block 71-1 on the base substrate and the orthographic projection of the anode main body portion on the base substrate have a first overlap region, and an orthographic projection of the second power supply block 71-2 on the base substrate and the orthographic projection of the anode main body portion on the base substrate have a second overlap region, the position and shape of the first overlap region and the position and shape of the second overlap region may be substantially mirror-symmetrical with respect to the first anode centerline OX of the anode. For example, the position and shape of the first overlap region and the position and shape of the second overlap region may be substantially mirror-symmetrical with respect to the first anode centerline OX of the third anode 90C. As another example, the position and shape of the first overlap region and the position and shape of the second overlap region may be substantially mirror-symmetrical with respect to the first anode centerline OX of the fourth anode 90D.

In an exemplary implementation, in the two first power supply lines 71 in two circuit units adjacent in the first direction X, the orthographic projection of the first power supply block 71-1 in one first power supply line 71 on the base substrate and the orthographic projection of the anode main body portion on the base substrate have a first overlap region, and the orthographic projection of the first power supply block 71-1 in the other first power supply line 71 on the base substrate and the orthographic projection of the anode body on the base substrate have a third overlap region, the positions and shapes of the first overlap region and the third overlap region may be substantially mirror-symmetrical with respect to the second anode centerline OY of the anode.

In an exemplary implementation, in the two first power supply lines 71 in two circuit units adjacent in the first direction X, the orthographic projection of the second power supply block 71-2 in one first power supply line 71 on the base substrate and the orthographic projection of the anode main body portion on the base substrate have a second overlap region, and the orthographic projection of the second power supply block 71-2 in the other first power supply line 71 on the base substrate and the orthographic projection of the anode body on the base substrate have a fourth overlap region, the positions and shapes of the second overlap region and the fourth overlap region may be substantially mirror-symmetrical with respect to the second anode centerline OY of the anode.

In an exemplary implementation, an orthographic projection of the at least one shield electrode 74 on the base substrate is at least partially overlapped with an orthographic projection of the anode main body portion of the at least one anode on the base substrate. For example, the orthographic projection of the at least one shield electrode 74 on the base substrate is at least partially overlapped with the orthographic projection of the anode main body portion of the third anode 90C on the base substrate. As another example, the orthographic projection of the at least one shield electrode 74 on the base substrate is at least partially overlapped with the orthographic projection of the anode main body portion of the fourth anode 90D on the base substrate.

In an exemplary implementation, an orthographic projection of the at least one shield electrode 74 on the base substrate is at least partially overlapped with an orthographic projection of the second anode centerline OY of the at least one anode on the base substrate. For example, the orthographic projection of the at least one shield electrode 74 on the base substrate is at least partially overlapped with the orthographic projection of the second anode centerline OY of the third anode 90C on the base substrate. As another example, the orthographic projection of the at least one shield electrode 74 on the base substrate is at least partially overlapped with the orthographic projection of the second anode centerline OY of the fourth anode 90D on the base substrate.

In an exemplary implementation, the orthographic projection of the anode connection portion of the at least one anode on the base substrate is not overlapped with the orthographic projection of the second connection electrode 52 on the base substrate.

In an exemplary implementation, the anode connection portion of the at least one anode may include a first connection sub-portion 90-1 and a second connection sub-portion 90-2, the first connection sub-portion 90-1 and the second connection sub-portion 90-2 are configured to avoid overlapping with the second connection electrode 52.

In an exemplary implementation, the anode connection portions of the first anode 90A and the second anode 90B may include at least first connection sub-portions 90-1 and second connection sub-portions 90-2, a first end of the first connection sub-portion 90-1 is connected to the anode main body portion, a second end of the first connection sub-portion 90-1 is connected to a first end of the second connection sub-portion 90-2 after the second end of the first connection sub-portion 90-1 extends in a direction away from the anode main body portion along the first direction X. A second end of the second connection sub-portion 90-2 extends in a direction away from the first connection sub-portion 90-1 along the second direction Y, so that the anode connection portions of the first anode 90A and the second anode 90B avoid the region where the second connection electrode 52 is located.

In an exemplary implementation, an orthographic projection of the first connection sub-portion 90-1 on the base substrate is not overlapped with the orthographic projection of the second connection electrode 52 on the base substrate, and an orthographic projection of the second connection sub-portion 90-2 on the base substrate is not overlapped with the orthographic projection of the second connection sub-portion 90-2 on the base substrate, so as to effectively reduce the parasitic capacitance of the second node N2.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation, a subsequent preparation process may include: forming a pattern of a pixel definition layer at first, then forming an organic emitting layer by using an evaporation process and inkjet printing process, then forming a cathode on the organic emitting layer, and then forming an encapsulation structure layer, herein the encapsulation structure layer may include a first encapsulation layer, a second encapsulation layer, and a third encapsulation layer which are stacked, the first encapsulation layer and the third encapsulation layer may be made of an inorganic material, the second encapsulation layer may be made of an organic material, and the second encapsulation layer is arranged between the first encapsulation layer and the third encapsulation layer, which may ensure that external water vapor cannot enter the light emitting structure layer.

A display substrate has the problem that an instantaneous large current appears when a light emitting signal line provides a conductive signal, which affects the display effect. It is found by research that the instantaneous large current is caused by the large parasitic capacitance at the second node N2. Since the third initial signal line in the pixel drive circuit is connected to the second node N2 through the eighth transistor T8, when the parasitic capacitance of the second node N2 is large, it is equivalent to the existence of a large capacitance at the second node N2 that stores a bias voltage (on bias) of the third initial signal line, and when the light emitting signal line provides a turned-on signal (the sixth transistor T6 is turned on), the amount of charge in the parasitic capacitance of the second node N2 is preferentially released, and an instantaneous large current appears.

An exemplary embodiment of the present disclosure provides a display substrate. Through layout adjustment and structure optimization, the parasitic capacitance of the second node N2 is effectively reduced, so that the parasitic capacitance of the second node N2 is reduced by 9.35 f, which effectively avoids the problem of instantaneous large current, greatly reduces the transient current when the sixth transistor T6 is turned on, and improves the display quality and display effect.

According to the present disclosure, the second connection electrode is configured not to be overlapped with the fourth scan signal line, thus not only the parasitic capacitance of the second node N2 can be reduced, but also the influence on the data signal write process can be reduced.

According to the present disclosure, the first scan signal line and the first shield line are arranged with unequal widths, and the second connection electrode is overlapped with the first scan signal line and the first shield line with smaller widths, thereby effectively reducing the parasitic capacitance between the second node N2 and the first scan signal line and the first shield line.

According to the present disclosure, the parasitic capacitance of the second node N2 can be minimized by setting the first power supply line to be not overlapped with the second connection electrode, the shield electrode to be not overlapped with the second connection electrode, and the anode connection portion to be not overlapped with the second connection electrode.

According to the present disclosure, by arranging a shield electrode between adjacent second connection electrodes, the shield electrode having a constant potential can effectively reduce the mutual influence between the second nodes N2 in the adjacent circuit units, and improve the driving performance of the pixel driving circuit.

According to the present disclosure, by arranging the first connection electrode to be overlapped with the first scan signal line, the parasitic capacitance between the first scan signal line and the first node N1 is increased, and the potential of the first node N1 is pulled down using the falling edge of the first scanning signal line, thereby increasing the current and effectively improving the display brightness.

According to the present disclosure, by arranging the first power supply line to be overlapped with the first connection electrode, the affect by data voltage jumps and other signals on the potential of the first node N1 can be effectively prevented, and the driving performance of the pixel drive circuit can be improved. According to the present disclosure, by arranging the first power supply line to be overlapped with the active layer of the second transistor, the characteristic drift of the oxide second transistor due to the irradiation of light can be prevented, and the electrical characteristics of the oxide second transistor are improved.

According to the present disclosure, the shielding electrode is arranged to be overlapped with the second anode centerline of the anode, and the first power supply line, the first power supply block and the second power supply block are arranged to be mirror-symmetric with respect to the second anode centerline, and the first power supply block and the second power supply block 71 are arranged to be mirror-symmetric with respect to the first anode centerline, so that the flatness of the anode can be effectively improved, the height difference of the anode can be avoided, and the luminous performance of the light-emitting devices in various regions can be guaranteed to be basically the same, so that not only a color deviation of a large viewing angle is avoided, but also the defects such as screen-off watermark are avoided, and the quality of the display substrate is improved.

According to the present disclosure, by arranging a first initial signal line whose main body portion extends in the first direction and a first initial connection line whose main body portion extends in the second direction, arranging a second initial signal line whose main body portion extends in the first direction and a second initial connection line whose main body portion extends in the second direction, and arranging a third initial signal line whose main body portion extends in the first direction and a third initial connection line whose main body portion extends in the second direction, the first initial signal lines, the second initial signal lines and the third initial signal lines respectively form a mesh communication structure, which not only effectively reduces a resistance of the initial signal line, reduces a voltage drop of an initial voltage, but also effectively improves uniformity of the initial voltage in the display substrate, effectively improves uniformity of the display, and improves the display quality.

The manufacturing process in the present disclosure may be compatible well with an existing manufacturing process, is simple in process implementation, is easy to implement, and has a high production efficiency, a low production cost, and a high yield.

The aforementioned structure and the preparation process thereof shown in the present disclosure are merely exemplary description. In an exemplary implementation, corresponding structures may be changed and patterning processes may be added or reduced according to actual needs, which is not limited here in the present disclosure.

In an exemplary implementation, the display substrate in the present disclosure may be applied to other display devices having pixel drive circuits, such as quantum dot displays and the like, which is not limited in the present disclosure.

The present disclosure also provides a preparation method for a display substrate, for preparing the display substrate according to the foregoing embodiments. In an exemplary implementation, the manufacturing method may include:
forming a drive circuit layer on a base substrate, herein the drive circuit layer includes a plurality of circuit units, at least one circuit unit includes at least a pixel drive circuit and a first power supply line, the first power supply line is configured to provide a first power supply signal to the pixel drive circuit; the at least one circuit unit further includes a shield electrode, herein the shield electrode is connected with the first power supply line; and
forming a light emitting structure layer on the drive circuit layer, herein the light emitting structure layer includes a plurality of light emitting units, at least one light emitting unit includes at least an anode, the anode includes an anode main body portion and an anode connection portion, one end of the anode connection portion is connected with the anode main body portion, and another end of the anode connection portion is connected with the pixel drive circuit; the at least one circuit unit further includes a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are as above, it should be noted that the above implementations are exemplary only rather than restrictive. Therefore, the present disclosure is not limited to what is specifically shown and described herein. Various modifications, substitutions or omissions may be made in forms and details of implementations without departing from the scope of the present disclosure.

1. A display substrate, comprising a drive circuit layer arranged on a base substrate and a light emitting structure layer arranged on a side of the drive circuit layer away from the base substrate; wherein the drive circuit layer comprises a plurality of circuit units, at least one circuit unit comprises at least a pixel drive circuit and a first power supply line, the first power supply line is configured to provide a first power supply signal to the pixel drive circuit; the light emitting structure layer comprises a plurality of light emitting units, at least one light emitting unit comprises at least an anode, the anode comprises an anode main body portion and an anode connection portion, one end of the anode connection portion is connected with the anode main body portion, and another end of the anode connection portion is connected with the pixel drive circuit; the at least one circuit unit further comprises a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.

2. The display substrate according to claim 1, wherein an orthographic projection of an anode main body portion of the at least one anode on the base substrate is at least partially overlapped with orthographic projections of two first power supply lines in two circuit units adjacent in the first direction on the base substrate, and the two first power supply lines are mirror-symmetrical with respect to the second anode centerline.

3. The display substrate according to claim 1, wherein at least one first power supply line is provided with a first power supply block and a second power supply block, an orthographic projection of an anode main body portion of the at least one anode on the base substrate is at least partially overlapped with orthographic projections of the first power supply block and the second power supply block on the base substrate, and the first power supply block and the second power supply block are mirror-symmetrical with respect to a first anode centerline, the first anode centerline is a straight line that bisects the anode main body portion in the second direction Y and extends along the first direction.

4. The display substrate according to claim 3, wherein the orthographic projection of the anode main body portion of the at least one anode on the base substrate is at least partially overlapped with orthographic projections of two first power supply blocks in two circuit units adjacent in the first direction on the base substrate, the two first power supply blocks are mirror-symmetrical with respect to the second anode centerline; the orthographic projection of the anode main body portion of the at least one anode on the base substrate is at least partially overlapped with orthographic projections of two second power supply blocks in the two circuit units adjacent in the first direction on the base substrate, the two second power supply blocks are mirror-symmetrical with respect to the second anode centerline.

5. The display substrate according to claim 1, wherein the pixel drive circuit comprises at least a second transistor as a compensation transistor and a third transistor as a drive transistor, a gate electrode of the second transistor is connected with a first scan signal line, a first electrode of the second transistor is connected with a second electrode of the third transistor through a second node electrode, and a second electrode of the second transistor is connected with a gate electrode of the third transistor through a first node electrode; an orthographic projection of the anode connection portion on the base substrate is not overlapped with an orthographic projection of the second node electrode on the base substrate.

6. The display substrate according to claim 5, wherein an orthographic projection of the first power supply line on the base substrate is not overlapped with an orthographic projection of the second node electrode on the base substrate.

7. The display substrate according to claim 5, wherein the shield electrode is arranged between second node electrodes of two circuit units adjacent in the first direction.

8. The display substrate according to claim 5, wherein an orthographic projection of the shield electrode on the base substrate is not overlapped with an orthographic projection of the second node electrode on the base substrate.

9. The display substrate according to claim 5, wherein the pixel drive circuit further comprises a fourth transistor as a data write transistor, wherein a gate electrode of the fourth transistor is connected with a fourth scan signal line, a first electrode of the fourth transistor is connected to a data signal line, a second electrode of the fourth transistor is connected with a first electrode of the third transistor, and the orthographic projection of the second node electrode on the base substrate is not overlapped with an orthographic projection of the fourth scan signal line on the base substrate.

10. The display substrate according to claim 5, wherein the first scan signal line comprises at least a first sub-scan line segment and a second sub-scan line segment connected with each other, wherein a width of the first sub-scan line segment is greater than a width of the second sub-scan line segment and the width is a dimension in the second direction; the orthographic projection of the second node electrode on the base substrate is not overlapped with an orthographic projection of the first sub-scan line segment on the base substrate, and the orthographic projection of the second node electrode on the base substrate is at least partially overlapped with an orthographic projection of the second sub-scan line segment on the base substrate.

11. The display substrate according to claim 5, wherein the at least one circuit unit further comprises a first shielding line, wherein the first shielding line comprises at least a first sub-shielding line segment and a second sub-shielding line segment connected with each other, a width of the first sub-shielding line segment is greater than a width of the second sub-shielding line segment, and the width is a dimension in the second direction; the orthographic projection of the second node electrode on the base substrate is not overlapped with an orthographic projection of the first sub-shielding line segment on the base substrate, and the orthographic projection of the second node electrode on the base substrate is at least partially overlapped with an orthographic projection of the second sub-scan line segment on the base substrate.

12. The display substrate according to claim 5, wherein an orthographic projection of the first node electrode on the base substrate is at least partially overlapped with an orthographic projection of the first scan signal line on the base substrate.

13. The display substrate according to claim 12, wherein a first end of the first node electrode is connected with the second electrode of the second transistor, and a second end of the first node electrode is connected with the gate electrode of the third transistor; the first end of the first node electrode is connected with a first compensation block, and an orthographic projection of the first compensation block on the base substrate is at least partially overlapped with the orthographic projection of the first scan signal line on the base substrate.

14. The display substrate according to claim 5, wherein an orthographic projection of the first power line on the base substrate is at least partially overlapped with an orthographic projection of the first node electrode on the base substrate.

15. The display substrate according to claim 5, wherein an orthographic projection of the first power line on the base substrate is at least partially overlapped with an orthographic projection of an active layer of the second transistor on the base substrate.

16. The display substrate according to claim 1, wherein the at least one circuit unit further comprises a first initial signal line extending along the first direction and a first initial connection line extending along the second direction, wherein the first initial signal line is configured to provide a first initial signal to the pixel drive circuit, and the first initial connection line is connected with the first initial signal line to form a mesh communication structure transmitting the first initial signal, and/or, the at least one circuit unit further comprises a second initial signal line extending along the first direction and a second initial connection line extending along the second direction, wherein the second initial signal line is configured to provide a second initial signal to the pixel drive circuit, and the second initial connection line is connected with the second initial signal line to form a mesh communication structure transmitting the second initial signal, and/or, the at least one circuit unit further comprises a third initial signal line extending along the first direction and a third initial connection line extending along the second direction, wherein the third initial signal line is configured to provide a third initial signal to the pixel drive circuit, and the third initial connection line is connected with the third initial signal line to form a mesh communication structure transmitting the third initial signal.

17. The display substrate according to claim 16, wherein at least one of the first initial connection line, the second initial connection line, and the third initial connection line comprises a first initial connection electrode and a second initial connection electrode connected with each other; in a direction perpendicular to the base substrate, the drive circuit layer comprises a plurality of conductive layers, the first initial connection electrode and the second initial connection electrode are arranged in different conductive layers.

18. A display apparatus, comprising the display substrate according to claim 1.

19. A method for manufacturing a display substrate, comprising:
forming a drive circuit layer on a base substrate, wherein the drive circuit layer comprises a plurality of circuit units, at least one circuit unit comprises at least a pixel drive circuit and a first power supply line, the first power supply line is configured to provide a first power supply signal to the pixel drive circuit; the at least one circuit unit further comprises a shield electrode, wherein the shield electrode is connected with the first power supply line; and
forming a light emitting structure layer on the drive circuit layer, wherein the light emitting structure layer comprises a plurality of light emitting units, at least one light emitting unit comprises at least an anode, the anode comprises an anode main body portion and an anode connection portion, one end of the anode connection portion is connected with the anode main body portion, and another end of the anode connection portion is connected with the pixel drive circuit; the at least one circuit unit further comprises a shield electrode, the shield electrode is connected with the first power line, an orthographic projection of at least one shield electrode on the base substrate is at least partially overlapped with an orthographic projection of a second anode centerline of at least one anode on the base substrate, the second anode centerline is a straight line that bisects the anode main body portion in a first direction and extends in a second direction, and the first direction intersects with the second direction.
